(19) United States
(12) Patent Application Publication
(10) Pub. No.: US 2026/0215203 A1
(43) Pub. Date: Jul. 23, 2026

(54) SYSTEMS AND METHODS FOR POROUS TOOL

(71) Applicant: IQE plc, St. Mellons, Cardiff (GB)

(72) Inventor: Rodney PELZEL, St. Mellons, Cardiff (GB)

(21) Appl. No.: 19/136,001

(22) PCT Filed: Dec. 6, 2023
(86) PCT No.: PCT/EP2023/084580

§ 371 Date: Jun. 5, 2025

(30) Foreign Application Priority Data
Dec. 12, 2022 (GB) 2218653.0

(51) Int. Cl. H10P 72/00

(52) U.S. Cl. CPC H10P 72/0426; H10P 72/0441; H10P 72/0616; H10P 72/0431

(57) ABSTRACT

A porous tool for porosifying a wafer includes an electrolytic cell a housing, a voltage source, and a controller The electrolytic cell includes a cathode an anode, and an electrolyte A diameter of the wafer is at least 200 mm. The housing encloses the electrolytic cell and is configured to receive the wafer for a porosification process. The housing includes a seal, an input line and an output line The controller is coupled to the housing and the voltage source. The controller is configured to control the porosification process of the wafer. Advantageously the porous tool can provide dry-in and dry-out full-scale (e.g., at least 200 mm diameter) wafer porosification, programmable wafer porosification, a closed cleanroom compatible processing environment, epitaxy and CMOS compatible processing, and automated large volume cassette-to-cassette processing.

### BACKGROUND

### Field

The present disclosure relates to porous apparatuses, systems, and methods, for example, a porous tool for dry-in and dry-out full-scale programmable wafer porosification, a closed cleanroom compatible processing environment, epitaxy and complementary metal-oxide-semiconductor (CMOS) compatible processing, and automated cassette-to-cassette processing.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and improve harmonic losses. A trap-rich layer (e.g., polycrystalline silicon, called polysilicon) is formed between the handle wafer and the BOX to minimize parasitic surface conduction effects that can adversely affect RF devices in the top device layer. In addition, to further improve substrate harmonic losses, high-resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates. Porous semiconductors can achieve high-resistivity properties on a standard low-resistivity CMOS silicon wafer, rather than a high-resistivity SOI wafer. Porosification can form a porous region with a particular thickness and porosity in a layer or substrate. For example, electrochemically etching a standard low-resistivity (e.g., 1 Ω·cm) silicon wafer can form a thick (e.g., greater than 10 microns) porous silicon surface layer. The porous etch can deplete free charge carriers within the silicon and increase a resistivity of the porous silicon layer by several orders of magnitude (e.g., from 1 Ω·cm to greater than 5,000 Ω·cm). The high-resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, current porosification techniques are capable of only porosifying a small portion of a substrate and require operator exposure to acid solutions (e.g., hydrofluoric (HF) acid). Further, current porosification techniques are not cleanroom compatible (e.g., Class 1, ISO 3) and also are not compatible with epitaxy or CMOS processing. In addition, current porosification techniques are not automated and are not capable of large volume cassette-to-cassette processing.

### SUMMARY

Accordingly, there is a need for a porous tool for dry-in and dry-out full-scale programmable wafer porosification, a closed cleanroom compatible (e.g., Class 1, ISO 3) processing environment, epitaxy and CMOS compatible processing, and automated large volume cassette-to-cassette processing.

In some aspects, a porous tool for porosifying a wafer can include an electrolytic cell, a housing, a voltage source, and a controller. In some aspects, the electrolytic cell can include a cathode, an anode, and an electrolyte. In some aspects, the wafer can be between the cathode and the anode. In some aspects, a diameter of the wafer is at least 200 mm. In some aspects, the housing can enclose the electrolytic cell. In some aspects, the housing can be configured to receive the wafer for a porosification process. In some aspects, the housing can include a seal, an input line, and an output line. In some aspects, the voltage source can be coupled to the cathode and the anode. In some aspects, the controller can be coupled to the housing and the voltage source. In some aspects, the controller can be configured to control the porosification process of the wafer. Advantageously the porous tool can provide dry-in and dry-out full-scale programmable wafer porosification, a closed cleanroom compatible (e.g., Class 1, ISO 3) processing environment, and epitaxy and CMOS compatible processing.

In some aspects, the diameter of the wafer is at least 300 mm. In some aspects, a diameter of the electrolytic cell is about 6 mm less than the diameter of the wafer. Advantageously the porous tool can accommodate full-scale (e.g., 300 mm diameter) wafer porosification and avoids porosification of small portions of a substrate.

In some aspects, the anode can include a conductive layer coupled to a backside of the wafer. In some aspects, the anode and/or the cathode can include a boron-doped diamond-like carbon. Advantageously the boron-doped diamond-like carbon anode and/or cathode can provide a wide voltage potential window even in aqueous electrolytes during porosification.

In some aspects, the housing can include polytetrafluoroethylene (PTFE). In some aspects, the housing can include a first seal and a second seal, the first seal coupled to a frontside of the wafer and the second seal coupled to a backside of the wafer. Advantageously the housing can provide a closed cleanroom compatible (e.g., Class 1, ISO 3) processing environment and reduces operator exposure to acid solutions (e.g., HF acid).

In some aspects, the electrolyte can include a first electrolyte between the cathode and the frontside of the wafer and a second electrolyte between the anode and the backside of the wafer. In some aspects, the first electrolyte can include a first acid solution of a first concentration, and the second electrolyte can include a second acid solution of a second concentration that is weaker than the first concentration. In some aspects, the first electrolyte can include an acid solution, and the second electrolyte can include a conductive solution. Advantageously the first and second electrolytes can improve control during a porosification process and reduce metal contamination in the formed porous layer.

In some aspects, the controller can be configured to control a current density per unit time applied to the wafer during the porosification process. Advantageously the controller can provide dry-in and dry-out full-scale programmable wafer porosification.

In some aspects, the porous tool can further include a wafer handling system configured to load and unload the wafer to and from the housing. Advantageously the porous tool with the wafer handling system can provide automated large volume cassette-to-cassette processing.

In some aspects, a porous tool system can include a porous tool, a wafer handling system, and a controller. In some aspects, the porous tool can be configured to porosify a wafer. In some aspects, the porous tool can include an electrolytic cell including a cathode, an anode, and an electrolyte; a housing enclosing the electrolytic cell and configured to receive the wafer for a porosification process, the housing including a seal, an input line, and an output line; and a voltage source coupled to the cathode and the anode. In some aspects, the wafer handling system can be configured to load and unload the wafer to and from the porous tool. In some aspects, the controller can be coupled to the porous tool and the wafer handling system and be configured to control the porosification process of the wafer. Advantageously the porous tool system can provide dry-in and dry-out full-scale programmable wafer porosification, a closed cleanroom compatible (e.g., Class 1, ISO 3) processing environment, epitaxy and CMOS compatible processing, and automated large volume cassette-to-cassette processing.

In some aspects, a diameter of the wafer is at least 200 mm. Advantageously the porous tool system can accommodate full-scale (e.g., at least 200 mm diameter) wafer porosification and avoid porosification of small portions of a substrate.

In some aspects, the porous tool system can be configured to load the wafer within the housing via the wafer handling system. In some aspects, the porous tool system can be configured to seal the wafer to the housing via the seal. In some aspects, the porous tool system can be configured to fill the housing with an electrolyte solution via the input line. In some aspects, the porous tool system can be configured to perform the porosification process of the wafer. In some aspects, the porous tool system can be configured to drain the housing of the electrolyte solution via the output line. In some aspects, the porous tool system can be configured to dry, for example spin rinse dry, the wafer within the housing. In some aspects, the porous tool system can be configured to unload the wafer via the wafer handling system after porosification. Advantageously the porous tool system can provide dry-in and dry-out full-scale programmable wafer porosification and automated large volume cassette-to-cassette processing.

In some aspects, the porous tool system can be configured to load the wafer within the housing via the wafer handling system. In some aspects, the porous tool system can be configured to seal the wafer to the housing via the seal. In some aspects, the porous tool system can be configured to fill the housing with deionized (DI) water via the input line. In some aspects, the porous tool system can be configured to perform a leak check of the sealed wafer. In some aspects, the porous tool system can be configured to drain the housing of the DI water via the output line. In some aspects, the porous tool system can be configured to fill the housing with an electrolyte solution via the input line. In some aspects, the porous tool system can be configured to perform the porosification process of the wafer. In some aspects, the porous tool system can be configured to drain the housing of the electrolyte solution via the output line. In some aspects, the porous tool system can be configured to flush the housing with DI water via the input line. In some aspects, the porous tool system can be configured to drain the housing of the DI water via the output line. In some aspects, the porous tool system can be configured to dry, for example spin rinse dry, the wafer within the housing. In some aspects, the porous tool system can be configured to unload the wafer via the wafer handling system after porosification. Advantageously the porous tool system can provide dry-in and dry-out full-scale programmable wafer porosification, reduce operator exposure to electrolyte solutions (e.g., HF acid), and provide automated large volume cassette-to-cassette processing.

In some aspects, the porous tool system can be configured to dilute the electrolyte solution with DI water until the electrolyte solution has a pH of about 7 (neutral) prior to draining the housing of the electrolyte solution. Advantageously diluting the electrolyte solution (e.g., acid solution) with DI water reduces hydrogen-terminated surfaces on the wafer and reduces contaminants on the porous layer.

In some aspects, the wafer handling system can be configured to automatically process a cassette of wafers. Advantageously the porous tool system can provide automated large volume cassette-to-cassette processing.

In some aspects, the porous tool system can further include a dryer coupled to the porous tool and configured to dry the wafer within the housing. In some aspects, the dryer can include a spin rinse dryer. Advantageously the porous tool system can provide a closed cleanroom compatible (e.g., Class 1, ISO 3) processing environment for post-processing the wafer (e.g., drying) and reduce contaminants on the wafer.

In some aspects, the porous tool system can further include a heater coupled to the wafer handling system and configured to heat the wafer. Advantageously the porous tool system can provide a closed cleanroom compatible (e.g., Class 1, ISO 3) processing environment for post-processing the wafer (e.g., heating) and reduce contaminants on the wafer.

In some aspects, a method for a dry-in and dry-out porosification process can include the ordered steps of: loading a wafer within a housing of a porous tool; sealing the wafer to the housing; filling the housing with an electrolyte solution to form an electrolytic cell; porosifying a portion of the wafer to form a porous layer; draining the housing of the electrolyte solution; drying the wafer within the housing; and unloading the wafer. Advantageously the method can provide dry-in and dry-out full-scale programmable wafer porosification, a closed cleanroom compatible (e.g., Class 1, ISO 3) processing environment, epitaxy and CMOS compatible processing, and automated large volume cassette-to-cassette processing.

In some aspects, porosifying can include holding the wafer vertically within the housing such that only a first side of the wafer is porosified. Advantageously porosification can be limited to one side (e.g., frontside) of the wafer.

In some aspects, the method can further include filling the housing with DI water prior to forming the electrolytic cell, performing a leak check of the sealed housing and wafer, and draining the housing of the DI water. Advantageously the method can provide a closed cleanroom compatible (e.g., Class 1, ISO 3) processing environment and reduces operator exposure to electrolyte solutions (e.g., HF acid).

In some aspects, the method can further include flushing the housing with DI water prior to drying the wafer, and draining the housing of the DI water. Advantageously the method can provide a closed cleanroom compatible (e.g., Class 1, ISO 3) processing environment and reduces operator exposure to electrolyte solutions (e.g., HF acid).

In some aspects, the method can further include adding a floating layer of alcohol to an upper surface of the DI water prior to draining the housing of the DI water thereby forming an alcohol coating on a frontside of the wafer. Advantageously the alcohol coating can increase a storage time of the porosified wafer prior to epitaxial growth and can reduce contaminants on the porous layer before epitaxial growth on the porous layer.

In some aspects, the method can further include diluting the electrolyte solution with DI water until the electrolyte solution has a pH of about 7 (neutral) prior to draining the housing of the electrolyte solution. Advantageously diluting the electrolyte solution (e.g., acid solution) with DI water reduces hydrogen-terminated surfaces on the wafer and reduces contaminants on the porous layer.

In some aspects, porosifying can include controlling a current density per unit time applied to the electrolytic cell via a controller. In some aspects, controlling can include monitoring and adjusting the current density per unit time via a dynamic feedback loop between the controller and the porous tool based on a characteristic of the formed porous layer. In some aspects, the characteristic of the porous layer can include a porosification rate, a porosification depth, a porosity, a resistivity, a surface roughness, or a combination thereof. Advantageously the controller can provide dry-in and dry-out full-scale programmable wafer porosification, improve fabrication uniformity, and increase manufacturing yield.

In some aspects, the method can further include heating the wafer. Advantageously the method can provide a closed cleanroom compatible (e.g., Class 1, ISO 3) processing environment for post-processing the wafer (e.g., heating) and reduce contaminants on the wafer.

In some aspects, a diameter of the wafer is at least 200 mm. Advantageously the method can provide full-scale (e.g., at least 200 mm diameter) wafer porosification and avoid porosification of small portions of a substrate.

In some aspects, the method can further include automatically processing and porosifying a cassette of wafers. Advantageously the method can provide automated large volume cassette-to-cassette processing.

In some aspects, the method can further include growing an epitaxial layer directly over the porous layer. In some aspects, the method can further include forming a semiconductor device in the epitaxial layer. Advantageously the method can improve manufacturing efficiency and improve manufacturing yield.

In some aspects, the method can further include forming a semiconductor device in or on the porous layer. In some aspects, the semiconductor device can include a passive device (e.g., an inductor, a filter, etc.). In some aspects, the semiconductor device can include a radio frequency (RF) device (e.g., an RF inductor, an RF filter, etc.). In some aspects, the method can further include forming a device, for example a passive radio frequency (RF) device, in the porous layer. Advantageously the method can improve manufacturing efficiency and improve manufacturing yield.

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5 is a schematic cross-sectional illustration of a dual bath porosification system, according to an exemplary aspect.

FIG. 6 is a schematic cross-sectional illustration of a porous tool, according to an exemplary aspect.

FIG. 7 is a schematic cross-sectional illustration of a porous tool, according to an exemplary aspect.

FIG. 8 is a schematic cross-sectional illustration of a porous tool system with a wafer handling system, according to an exemplary aspect.

FIG. 9 is a schematic cross-sectional illustration of a porous layered structure, according to an exemplary aspect.

FIG. 10 is a schematic cross-sectional illustration of a porous layered structure, according to an exemplary aspect.

FIG. 11 is a schematic cross-sectional illustration of a porous layered structure, according to an exemplary aspect.

FIG. 12 is a schematic cross-sectional illustration of a porous layered structure, according to an exemplary aspect.

FIG. 13 is a schematic manufacturing diagram for forming the porous layered structure shown in FIG. 9, according to an exemplary aspect.

FIG. 14 is a schematic manufacturing diagram for forming the porous layered structure shown in FIG. 10, according to an exemplary aspect.

FIG. 15 is a schematic manufacturing diagram for forming the porous layered structure shown in FIG. 11, according to an exemplary aspect.

FIG. 16 is a schematic manufacturing diagram for forming the porous layered structure shown in FIG. 12, according to an exemplary aspect.

FIG. 17 is a flow diagram for forming a porous layered structure using a dry-in and dry-out wafer porosification process, according to an exemplary aspect.

FIG. 18 is a flow diagram for forming a porous layered structure using a dry-in and dry-out wafer porosification process, according to an exemplary aspect.

FIG. 19 is a flow diagram for forming a porous layered structure using a dry-in and dry-out wafer porosification process, according to an exemplary aspect.

FIG. 20 is a flow diagram for forming a porous layered structure using a dry-in and dry-out wafer porosification process, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, ±2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}Ga_{0.75} As means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur(S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InP, InSb, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 20° towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100>means the face of cubic crystal structure and encompasses [100], [010], and [001] orientations using the Miller indices. Similarly, for example, <0001>encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 10 microns) and porosity (e.g., about 35% to 65%) in a layer or substrate, and achieve high-resistivity (e.g., greater than 5,000 22 cm) on a standard CMOS wafer (e.g., silicon wafer). The high-resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

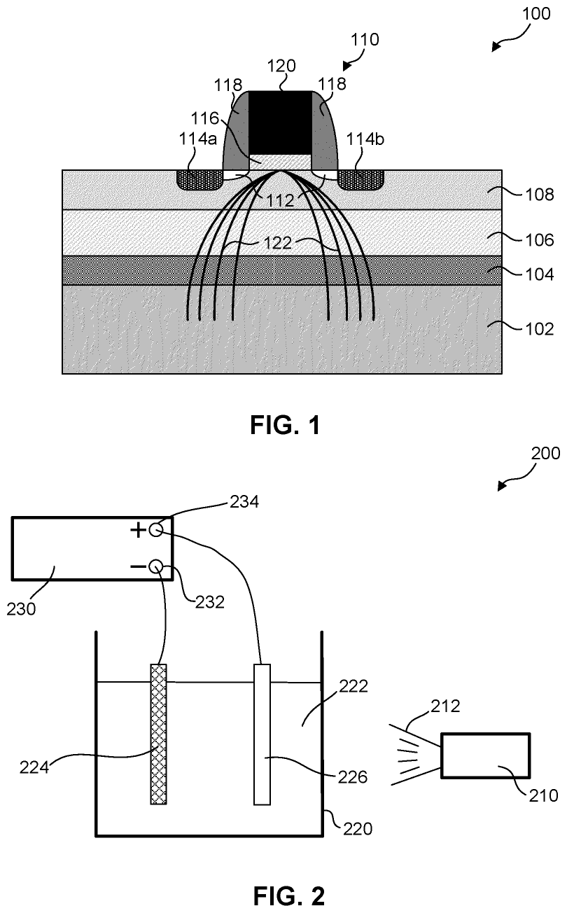

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polycrystalline silicon, called polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

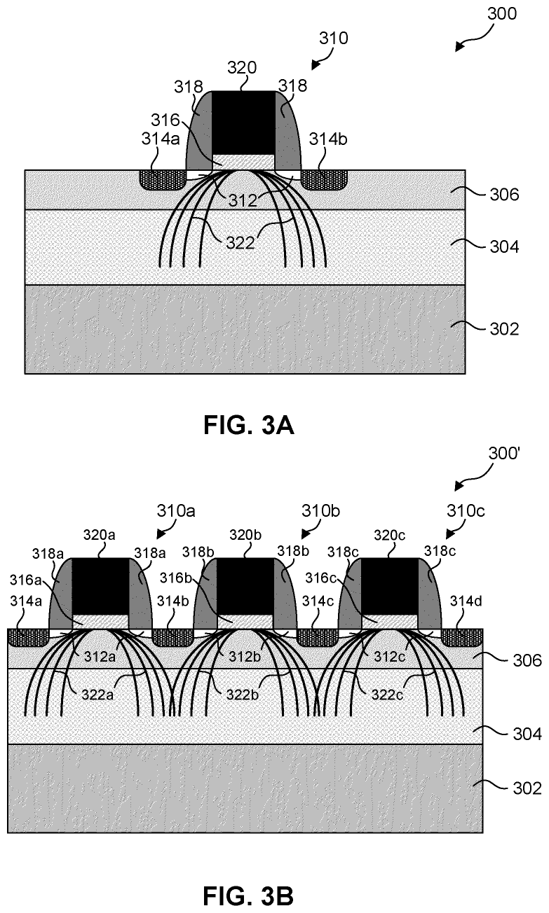

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is sealed and not exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm² to about 350 mA/cm² . For example, the electrolyte current density can be about 10 mA/cm² to about 100 mA/cm². In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 50 mA/cm² ) through substrate 226 from cathode 232 to anode 234 for a specified time (e.g., for 10 seconds to 15 minutes). In some aspects, the porosification process can be carried out in a constant voltage mode (e.g., DC bias of about 5 V to about 25 V) and controlled by monitoring an etching current signal. In some aspects, the porosification process can be carried out in a constant current mode (e.g., DC current of about 5 A to about 25 A) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, and III-V semiconductors. In some aspects, substrate 226 can be doped prior to porosification to adjust a resistivity of substrate 226, for example, to a low-resistivity in a range of about 0.1 Ω·cm to 10 Ω·cm. In some aspects, electrolyte 222 can include a mixture of HF and deionized water, for example, having a ratio of (5:2) and a surfactant (1 ml/l) (e.g., an alcohol). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

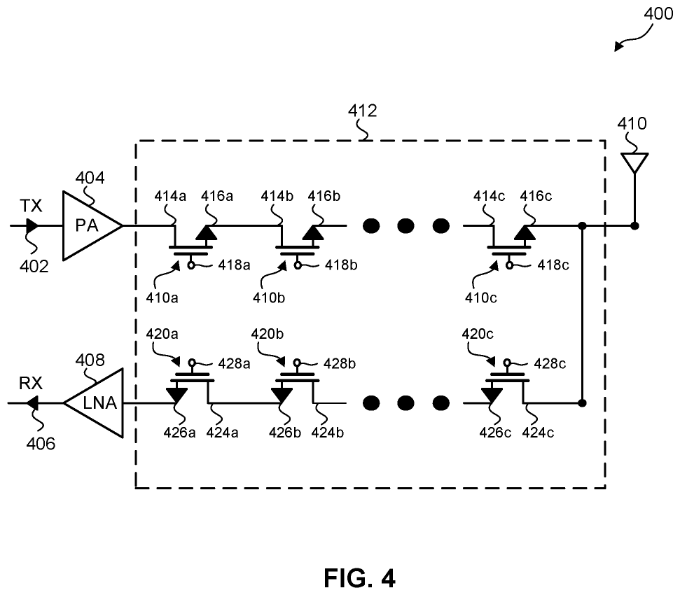

FIGS. 3A and 3B illustrate porous layered structures 300, 300′, according to exemplary aspects. Porous layered structures 300, 300′ can be configured to reduce signal leakage and suppress RF fringing fields (bleeding). In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high-resistivity porous layer 304 (e.g., greater than about 5,000 Ω·cm) prevents RF field lines 322 from semiconductor device 310 from penetrating (bleeding) into substrate 302. In some aspects, porous layered structure 300 suppresses harmonic losses, reduces crosstalk, and reduces parasitic surface conduction effects.

In some aspects, substrate 302 can comprise any suitable substrate having a predetermined crystallographic orientation, including but not limited to silicon, germanium, and III-V semiconductors. In some aspects, substrate 302 can be doped prior to porosification to adjust a resistivity of substrate 302, for example, to a low-resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 10 microns. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, Group IV semiconductors, and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

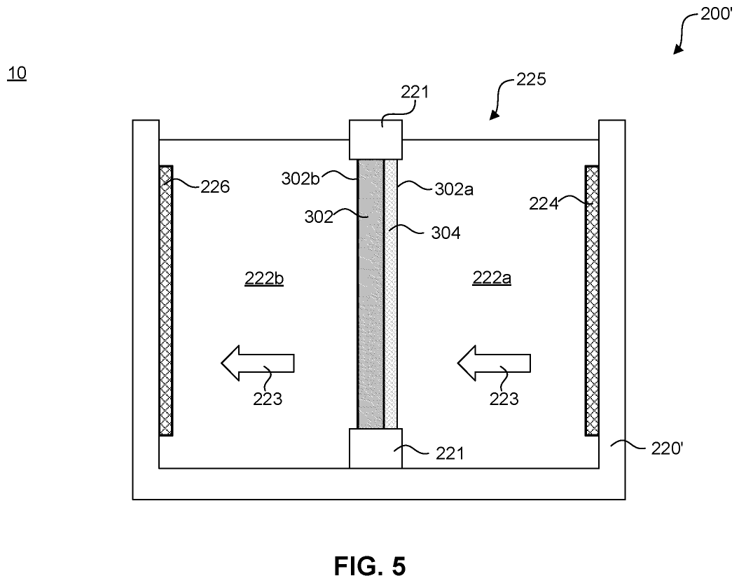

FIG. 5 illustrates dual bath porosification system 200′, according to an exemplary aspect. Dual bath porosification system 200′ can be configured to form one or more porous layers in a layer or substrate. Dual bath porosification system 200′ can be further configured to arrange a substrate 302 in a vertical configuration 10 (e.g., vertically aligned). Dual bath porosification system 200′ can be further configured to utilize a liquid backside (anode) contact to the layer or substrate thereby reducing metal contamination in the formed porous layer. Although dual bath porosification system 200′ is shown in FIG. 5 as a stand-alone apparatus and/or system, aspects of this disclosure can be used with other apparatuses, systems, and/or methods, for example, porous tool 300″, porous tool 300″′, porous tool system 800, porous layered structure 300″, porous layered structure 300″′, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

The aspects of porosification system 200 shown in FIG. 2, for example, and the aspects of dual bath porosification system 200′ shown in FIG. 5 may be similar. Similar reference numbers are used to indicate features of the aspects of porosification system 200 shown in FIG. 2 and the similar features of the aspects of dual bath porosification system 200′shown in FIG. 5.

As shown in FIG. 5, dual bath porosification system 200′can include dual bath 220′. Dual bath 220′can be configured to flow current 223 through substrate 302 from cathode 224 to anode 226 to form porous layer 304 on substrate 302. In some aspects, only frontside 302a of substrate 302 can be porosified to form porous layer 304, for example, with first electrolyte 222a (e.g., 40% electrolyte concentration) having an electrolyte concentration greater than second electrolyte 222 b (e.g., 4% electrolyte concentration) thereby isolating porosification to only frontside 302a of substrate 302. In some aspects, dual bath 220′ can include polytetrafluoroethylene (PTFE), fluoropolymers, or any other electrolyte resistive (e.g., HF acid) material. In some aspects, cathode 224 and anode 226 can include any suitable conductor (e.g., metal, Cu, Al, Pt, etc.). For example, cathode 224 and anode 226 can include a boron-doped diamond-like carbon. In some aspects, cathode 224 and anode 226 can include a doped semiconductor, for example, doped silicon (e.g., p-type). In some aspects, cathode 224 and anode 226 can include boron-doped diamond (BDD). For example, cathode 224 and anode 226 can each include a silicon wafer coated with BDD. In some aspects, cathode 224 and anode 226 can be connected to a current source (e.g., current source 230 shown in FIG. 2) to form an electrolyte current.

Dual bath 220′can include substrate holder 221, first electrolyte 222a, and second electrolyte 222b. Substrate holder 221 can be configured to secure substrate 302 in dual bath 220′during a porosification process. In some aspects, substrate holder 221 can adjust a distance between substrate 302 and cathode 224 and a distance between substrate 302 and anode 226. First electrolyte 222 a can be configured to flow current 223 from cathode 224 to substrate 302 during a porosification process (e.g., EC etching). In some aspects, first electrolyte 222a can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, first electrolyte 222a can include buffered HF acid. In some aspects, first electrolyte 222a can have an electrolyte concentration between about 30% to about 50%. For example, first electrolyte 222a can include buffered HF acid having an acid concentration of about 40%.

Second electrolyte 222 b can be configured to flow current 223 from substrate 302 to anode 226 during a porosification process (e.g., EC etching). In some aspects, second electrolyte 222b can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, second electrolyte 222b can include buffered HF acid. In some aspects, second electrolyte 222b can include a liquid metal (e.g., mercury (Hg), tin (Sn), cesium (Cs), gallium (Ga), etc.), a metallic solution (e.g., metal nanoparticles in DI water), or any other suitable conductive liquid. For example, second electrolyte 222b can include Hg. In some aspects, second electrolyte 222b can have an electrolyte concentration between about 1% to about 10%. For example, second electrolyte 222 b can include buffered HF acid having an acid concentration of about 4%. In some aspects, a ratio of electrolyte concentration of first and second electrolytes 222 a, 222 b (first: second) can be between about 4 to about 40. For example, the ratio of acid concentration of first and second electrolytes 222a, 222b can be about 10.

### Exemplary Porous Tools

As discussed above, current porosification techniques are capable of only porosifying a small portion of a substrate and require operator exposure to electrolyte solutions (e.g., HF acid). Further, current porosification techniques are not cleanroom compatible (e.g., Class 1, ISO 3) and also are not compatible with epitaxy or CMOS processing which require full wafers. In addition, current porosification techniques are not automated and are not capable of large volume cassette-to-cassette processing.

Aspects of porous tool apparatuses, systems, and methods as discussed below can provide dry-in and dry-out full-scale (e.g., at least 200 mm diameter) programmable wafer porosification, a closed cleanroom compatible (e.g., Class 1, ISO 3) processing environment, epitaxy and CMOS compatible processing, and automated large volume cassette-to-cassette processing (e.g., twenty-five wafers).

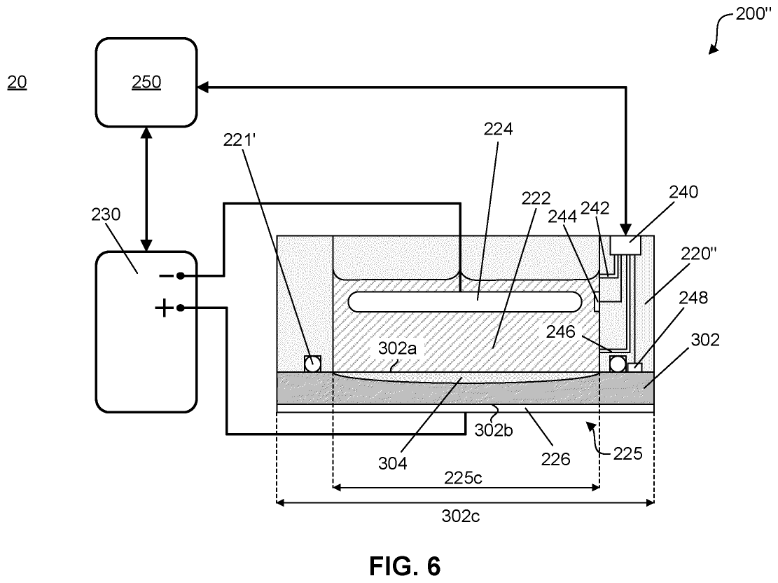

FIG. 6 illustrates porous tool 200″, according to an exemplary aspect. Porous tool 200″ can be configured to provide dry-in and dry-out full-scale (e.g., at least 200 mm diameter) programmable wafer porosification. Porous tool 200″ can be further configured to arrange a wafer 302 in a horizontal configuration 20 (e.g., horizontally aligned). Porous tool 200″ can be further configured to provide a closed cleanroom compatible (e.g., Class 1, ISO 3) processing environment and reduce operator exposure to electrolyte solutions (e.g., HF acid). Porous tool 200″ can be further configured to be compatible with epitaxy and CMOS processing. Porous tool 200″ can be further configured to provide automated large volume cassette-to-cassette processing (e.g., twenty-five wafers) and improve manufacturing yield. Although porous tool 200″ is shown in FIG. 6 as a stand-alone apparatus and/or system, aspects of this disclosure can be used with other apparatuses, systems, and/or methods, for example, dual bath porosification system 200′, porous tool 300″′, porous tool system 800, porous layered structure 300″, porous layered structure 300″′, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

The aspects of porosification systems 200, 200′ shown in FIGS. 2 and 5, for example, and the aspects of porous tool 200″ shown in FIG. 6 may be similar. Similar reference numbers are used to indicate features of the aspects of porosification systems 200, 200′shown in FIGS. 2 and 5 and the similar features of the aspects of porous tool 200″ shown in FIG. 6.

As shown in FIG. 6, porous tool 200″ can include electrolytic cell 225, housing 220″, voltage source 230, and controller 250. Electrolytic cell 225 can be configured to porosify a wafer 302 with an electrolyte current to form porous layer 304. As shown in FIG. 6, electrolytic cell 225 can include cathode 224, anode 226, and electrolyte 222. In some aspects, electrolytic cell 225 can have a diameter that is less than a diameter of wafer 302. For example, as shown in FIG. 6, electrolytic cell 225 can have internal diameter 225c (e.g., 194 mm) that is about 6 mm less than diameter 302 c (e.g., 200 mm) of wafer 302.

In some aspects, anode 226 can include a conductive layer coupled to a backside of a wafer 302. For example, as shown in FIG. 6, anode 226 can be a conductive contact (e.g., backside conductive layer 303 shown in FIG. 10) on backside 302b of wafer 302. In some aspects, cathode 224 and/or anode 226 can include a boron-doped diamond-like carbon. For example, cathode 224 and anode 226 both include a boron-doped diamond-like carbon (BDDLC) electrode. In some aspects, electrolyte 222 can include an electrolyte solution to facilitate porosification of wafer 302 (e.g., EC etching). For example, electrolyte 222 can include buffered HF acid. In some aspects, electrolyte 222 can have an electrolyte concentration between about 30% to about 50%. For example, electrolyte 222 can include buffered HF acid having an acid concentration of about 40%.

As shown in FIG. 6, a wafer 302 can be arranged between cathode 224 and anode 226 of electrolytic cell 225 during a porosification process. Wafer 302 can include any suitable wafer having a predetermined crystallographic orientation, including but not limited to silicon, germanium, Group IV semiconductors, and III-V semiconductors. In some aspects, wafer 302 can have a diameter of at least 200 mm. For example, as shown in FIG. 6, wafer 302 can have diameter 302 c that is at least 200 mm. In some aspects, diameter 302 c of wafer 302 can be at least 300 mm. For example, wafer 302 can be a 300 mm silicon wafer, for example Si(100).

Housing 220″ can be configured to enclose electrolytic cell 225 and receive a wafer 302 for a porosification process. As shown in FIG. 6, housing 220″ can include seal 221′, input line 242, electrolyte detector 244, output line 246, leak detector 248, and housing controller 240. In some aspects, housing 220″ can include polytetrafluoroethylene (PTFE), fluoropolymers, or any other electrolyte resistive (e.g., HF acid) material. Seal 221′can be configured to seal a wafer 302 within electrolytic cell 225. In some aspects, as shown in FIG. 6, seal 221′can be coupled to frontside 302a of wafer 302. In some aspects, seal 221′can include an O-ring (e.g., PTFE). In some aspects, a compressive force and/or negative pressure can be applied between wafer 302 and housing 220″ to form a liquid-tight seal.

Input line 242 can be configured to flow electrolyte 222 into electrolytic cell 225 onto a wafer 302 (e.g., dry-in process). As shown in FIG. 6, input line 242 can be coupled to electrolytic cell 225 and housing controller 240. In some aspects, input line 242 can flow DI water, an alkali solution, and/or an electrolyte solution (e.g., HF acid) into electrolyte 222 in order to change a concentration (e.g., pH level) of electrolyte 222. In some aspects, electrolyte detector 244 can be configured to measure a concentration (e.g., pH level) of electrolyte 222. For example, as shown in FIG. 6, electrolyte detector 244 can be coupled to electrolyte 222 and housing controller 240.

Output line 246 can be configured to flow electrolyte 222 out of electrolytic cell 225 (e.g., dry-out process). As shown in FIG. 6, output line 246 can be coupled to electrolytic cell 225 and housing controller 240. In some aspects, output line 242 can flow DI water, an alkali solution, and/or an electrolyte solution (e.g., HF acid) out of electrolyte 222 in order remove electrolyte 222 from wafer 302. In some aspects, leak detector 248 can be configured to perform a leak check of seal 221′on wafer 302 prior to a porosification process. For example, as shown in FIG. 6, leak detector 248 can be between frontside 302a of wafer 302 and housing 220″, exterior to seal 221′, and coupled to housing controller 240. In some aspects, wafer 302 can be sealed within electrolytic cell 225 by seal 221′, input line 242 can flow DI water into electrolytic cell 225, and leak detector 248 can perform a leak check.

Housing controller 240 can be configured to control operations of electrolytic cell 225, input line 242, and output line 246 and receive feedback signals from electrolyte detector 244 and leak detector 248. As shown in FIG. 6, housing controller 240 can be coupled to input line 242, electrolyte detector 244, output line 246, leak detector 248, and controller 250. In some aspects, housing controller 240 can control electrolyte 222 flow into and out of electrolytic cell 225. In some aspects, housing controller 240 can control electrolyte 222 concentration (e.g., pH level) in electrolytic cell 225. In some aspects, housing controller 240 can send and receive signals to and from controller 250. For example, a feedback loop can be established between controller 250 and housing controller 240 to control operations of housing 220″. In some aspects, housing 220″ can omit electrolyte detector 244. In some aspects, housing 220″ can omit leak detector 248.

Voltage source 230 can be configured to provide voltage to cathode 224 and anode 226. As shown in FIG. 6, voltage source 230 can be coupled to cathode 224 and anode 226. In some aspects, voltage source 230 can control voltage (e.g., current density) in electrolytic cell 225. In some aspects, voltage source 230 can send and receive signals to and from controller 250. For example, a feedback loop can be established between controller 250 and voltage source 230 to control voltages applied to electrolytic cell 225.

Controller 250 can be configured to control a porosification process of wafer 302. As shown in FIG. 6, controller 250 can be coupled to voltage source 230 and housing controller 240. In some aspects, controller 250 can control a current density per unit time (e.g., etch current density (mA/cm²)/etch time (s)) applied to wafer 302 during a porosification process to form porous layer 304. For example, the current density per unit time can be monitored and adjusted by voltage source 230. In some aspects, controller 250 can control a concentration of electrolyte 222 applied to wafer 302 during a porosification process to form porous layer 304. For example, the concentration (e.g., pH level) can be monitored and adjusted by housing controller 240.

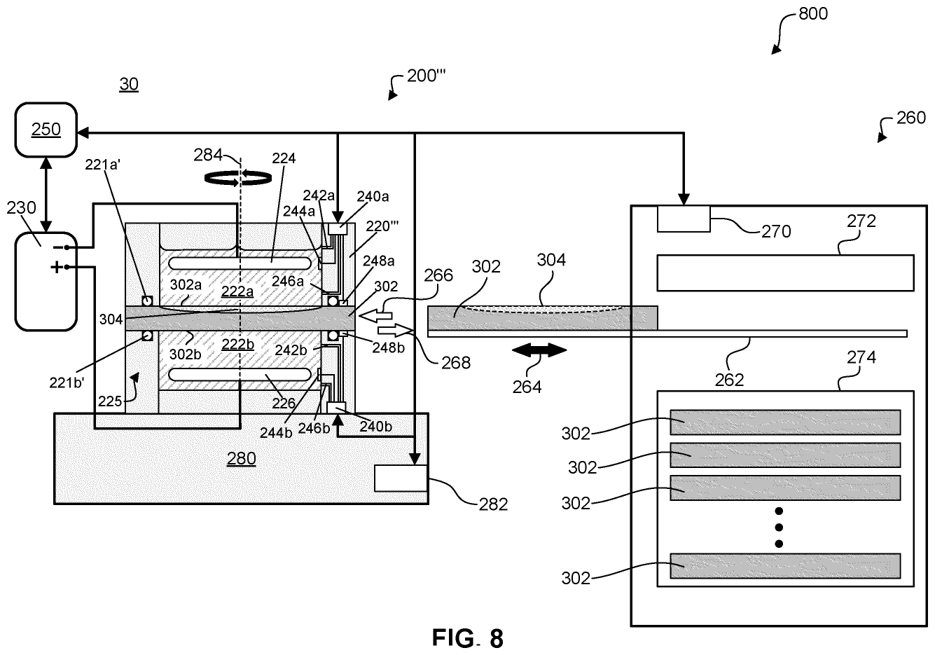

In some aspects, controller 250 can establish a dynamic feedback loop to monitor and adjust a current density per unit time applied to wafer 302 during a porosification process based on a characteristic of porous layer 304. For example, the characteristic can include a porosification rate, a porosification depth, a porosity, a resistivity, a surface roughness, or a combination thereof. In some aspects, the dynamic feedback loop can use closed control or open control. In some aspects, controller 250 can implement a plurality of programmable steps (e.g., a recipe) for a porosification process to wafer 302. For example, controller 250 can implement up to a hundred programmable steps per recipe. In some aspects, porous tool 200″ can further include a wafer handling system configured to load and unload wafer 302 to and from housing 220″. For example, porous tool 200″ can include wafer handling system 260 shown in FIG. 8.

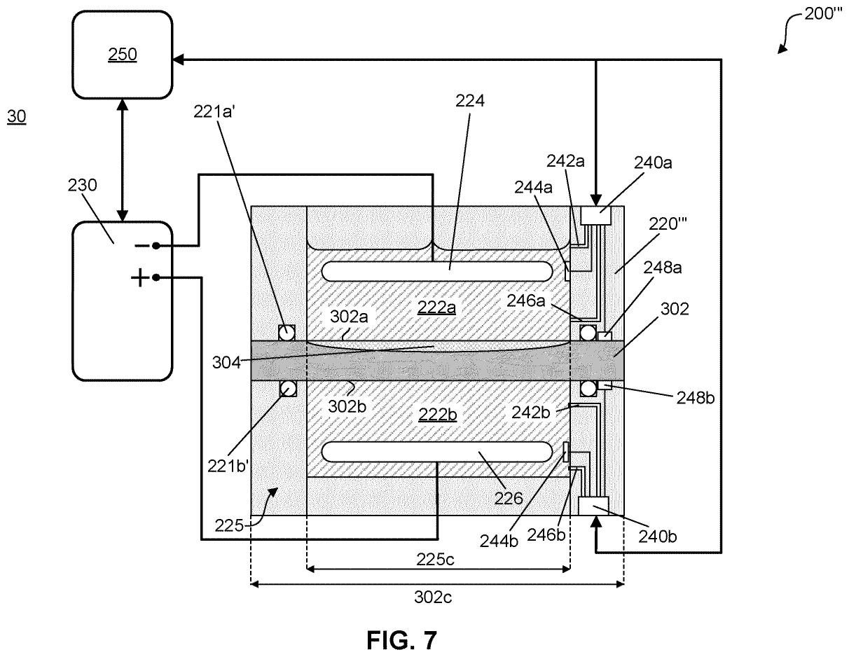

The aspects of porous tool 200″ shown in FIG. 6, for example, and the aspects of porous tool 200″′ shown in FIG. 7 may be similar. Similar reference numbers are used to indicate features of the aspects of porous tool 200″ shown in FIG. 6 and the similar features of the aspects of porous tool 200″′ shown in FIG. 7.

FIG. 7 illustrates porous tool 200″, according to an exemplary aspect. Porous tool 200″′ can be configured to utilize a liquid backside (anode) contact to wafer 302 thereby reducing metal contamination in porous layer 304. Porous tool 200″ can be further configured to arrange a wafer 302 in a horizontal configuration 30 (e.g., horizontally aligned). Although porous tool 200′″ is shown in FIG. 7 as a stand-alone apparatus and/or system, aspects of this disclosure can be used with other apparatuses, systems, and/or methods, for example, dual bath porosification system 200′, porous tool 300″, porous tool system 800, porous layered structure 300″, porous layered structure 300″′, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

As shown in FIG. 7, porous tool 200″′ can include electrolytic cell 225, housing 220″, voltage source 230, and controller 250. Electrolytic cell 225 can be configured to porosify a wafer 302 with an electrolyte current to form porous layer 304. As shown in FIG. 7, electrolytic cell 225 can include cathode 224, anode 226, first electrolyte 222a, and second electrolyte 222b.

First electrolyte 222a can be configured to flow current from cathode 224 to a wafer 302 during a porosification process (e.g., EC etching). In some aspects, first electrolyte 222a can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, first electrolyte 222a can include buffered HF acid. In some aspects, first electrolyte 222a can have an electrolyte concentration between about 30% to about 50%. For example, first electrolyte 222 a can include buffered HF acid having an acid concentration of about 40%.

Second electrolyte 222b can be configured to flow current from wafer 302 to anode 226 during a porosification process (e.g., EC etching). In some aspects, second electrolyte 222b can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, second electrolyte 222b can include buffered HF acid. In some aspects, second electrolyte 222b can have an electrolyte concentration between about 1% to about 10%. For example, second electrolyte 222b can include buffered HF acid having an acid concentration of about 4%.

In some aspects, a ratio of electrolyte concentration of first and second electrolytes 222a, 222b (first: second) can be between about 4 to about 40. For example, the ratio of electrolyte concentration of first and second electrolytes 222a, 222 b can be about 10. In some aspects, first electrolyte 222a can include a first acid solution of a first concentration and second electrolyte 222b can include a second acid solution of a second concentration that is weaker than the first concentration. For example, first electrolyte 222a can include buffered HF acid at a concentration between about 35% and about 45% and second electrolyte 222 b can include buffered HF acid at a concentration between about 2% and about 6%.

In some aspects, second electrolyte 222b can include a liquid metal (e.g., Hg, Sn, Cs, Ga, etc.), a metallic solution (e.g., metal nanoparticles in DI water), or any other suitable conductive liquid. For example, second electrolyte 222b can include Hg. In some aspects, first electrolyte 222a can include an acid solution and second electrolyte 222b can include a conductive solution. For example, first electrolyte 222a can include buffered HF acid and second electrolyte 222b can include liquid Hg.

The aspects of housing 220″ shown in FIG. 6, for example, and the aspects of housing 220′′ shown in FIG. 7 may be similar. Similar reference numbers are used to indicate features of the aspects of housing 220″ shown in FIG. 6 and the similar features of the aspects of housing 220″′ shown in FIG. 7.

Housing 220″′ can be configured to enclose electrolytic cell 225 and receive a wafer 302 for a porosification process. As shown in FIG. 7, housing 220″′ can include first and second seals 221a', 221b', first and second input lines 242a, 242b, first and second electrolyte detectors 244a, 244b, first and second output lines 246a, 246b, first and second leak detectors 248a, 248b, and first and second housing controllers 240a, 240b. In some aspects, housing 220″ can include first seal 221 a′ coupled to frontside 302a of wafer 302 and second seal 221b′ coupled to backside 302b of wafer 302. In some aspects, housing 220″′ can omit first and second electrolyte detectors 244a, 244b. In some aspects, housing 220′″ can omit first and second leak detectors 248a, 248b,

First and second input lines 242a, 242b can be configured to flow first and second electrolytes 222 a, 222 b into electrolytic cell 225 onto frontside 302a and backside 302 b of a wafer 302, respectively (e.g., dry-in process). In some aspects, first and second electrolyte detectors 244a, 244b can be configured to measure concentrations (e.g., pH levels) of first and second electrolytes 222a, 222b, respectively. For example, as shown in FIG. 7, first and second electrolyte detectors 244a, 244b can be coupled to first and second electrolytes 222a, 222b and first and second housing controllers 240a, 240b, respectively. First and second output lines 246a, 246b can be configured to flow first and second electrolytes 222a, 222b out of electrolytic cell 225, respectively (e.g., dry-out process). In some aspects, first and second leak detectors 248a, 248b can be configured to perform leak checks of first seal 221 a′ on frontside 302a and second seal 221b′ on backside 302 b, respectively, prior to a porosification process. For example, as shown in FIG. 7, first and second leak detectors 248 a, 248 b can be between frontside 302a and backside 302b of wafer 302 and housing 220″′, exterior to first and second seals 221a', 221b', and coupled to first and second housing controllers 240a, 240b, respectively.

First and second housing controllers 240a, 240b can be configured to control operations of electrolytic cell 225, first and second input lines 242a, 242b, and first and second output lines 246a, 246b, respectively. In some aspects, first and second housing controllers 240a, 240b can be further configured to receive feedback signals from first and second electrolyte detectors 244a, 244b and/or first and second leak detectors 248a, 248b, respectively.

Controller 250 can be configured to control a porosification process of a wafer 302. As shown in FIG. 7, controller 250 can be coupled to voltage source 230 and first and second housing controllers 240a, 240b. In some aspects, controller 250 can control a current density per unit time (e.g., etch current density (mA/cm²)/etch time (s)) applied to wafer 302 during a porosification process to form porous layer 304. For example, the current density per unit time can be monitored and adjusted by voltage source 230. In some aspects, controller 250 can control concentrations of first and second electrolytes 222a, 222b applied to wafer 302 during a porosification process to form porous layer 304. For example, the concentrations (e.g., pH levels) can be monitored and adjusted by first and second housing controllers 240a, 240b.

In some aspects, controller 250 can establish a dynamic feedback loop to monitor and adjust a current density per unit time applied to wafer 302 during a porosification process based on a characteristic of porous layer 304. For example, the characteristic can include a porosification rate, a porosification depth, a porosity, a resistivity, a surface roughness, or a combination thereof. In some aspects, the dynamic feedback loop can use closed control or open control. In some aspects, controller 250 can implement a plurality of programmable steps (e.g., a recipe) for a porosification process to wafer 302. For example, controller 250 can implement up to a hundred programmable steps per recipe. In some aspects, porous tool 200′″ can further include a wafer handling system configured to load and unload wafer 302 to and from housing 220″′. For example, porous tool 200″′ can include wafer handling system 260 shown in FIG. 8.

In some aspects, porous tool 200″′ can include a dryer configured to dry a wafer 302 within housing 220′″. For example, as shown in FIG. 8, porous tool 200″′ can include dryer 280 coupled to housing 220″′. In some aspects, dryer 280 can include a rotational dryer. For example, as shown in FIG. 8, dryer 280 can rotate wafer 302 about a central axis 284 in order to dry wafer 302 after porosification process. In some aspects, dryer 280 can include a spin rinse dryer.

### Exemplary Porous Tool System

FIG. 8 illustrates porous tool system 800 with porous tool 200″′ and wafer handling system 260, according to an exemplary aspect. Porous tool system 800 can be configured to provide dry-in and dry-out full-scale (e.g., at least 200 mm diameter) programmable wafer porosification. Porous tool system 800 can be further configured to provide a closed cleanroom compatible (e.g., Class 1, ISO 3) processing environment and reduce operator exposure to electrolyte solutions (e.g., HF acid). Porous tool system 800 can be further configured to be compatible with epitaxy and CMOS processing. Porous tool system 800 can be further configured to provide automated large volume cassette-to-cassette processing (e.g., twenty-five wafers, fifty wafers, a hundred wafers, etc.) and improve manufacturing yield. In some aspects, porous tool system 800 can be further configured to arrange a wafer 302 in a horizontal configuration 30 (e.g., horizontally aligned), for example, as shown in FIG. 8. In some aspects, porous tool system 800 can be further configured to arrange a wafer 302 in a vertical configuration 10 (e.g., vertically aligned), for example, as shown in FIG. 5.

Although porous tool system 800 is shown in FIG. 8 as a stand-alone apparatus and/or system, aspects of this disclosure can be used with other apparatuses, systems, and/or methods, for example, dual bath porosification system 200′, porous tool 300″, porous tool 300″′, porous layered structure 300″, porous layered structure 300″′, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

The aspects of porous tool 200′″ shown in FIG. 7, for example, and the aspects of porous tool system 800 shown in FIG. 8 may be similar. Similar reference numbers are used to indicate features of the aspects of porous tool 200′″ shown in FIG. 7 and the similar features of the aspects of porous tool system 800 shown in FIG. 8.

As shown in FIG. 8, porous tool system 800 can include porous tool 200″′ and wafer handling system 260. In some aspects, porous tool 200′″ can include a dryer configured to dry wafer 302 within housing 220′″. For example, as shown in FIG. 8, porous tool 200″′ can include dryer 280 coupled to housing 220″′. In some aspects, dryer 280 can include a rotational dryer. For example, as shown in FIG. 8, dryer 280 can rotate wafer 302 about a central axis 284 in order to dry wafer 302 after a porosification process. In some aspects, dryer 280 can include a spin rinse dryer. In some aspects, as shown in FIG. 8, dryer 280 can include dryer controller 282 coupled to controller 250. In some aspects, dryer controller 282 can be configured to control operations of dryer 280 and can send and receive signals to and from controller 250. For example, a feedback loop can be established between controller 250 and dryer controller 282 to control operations of dryer 280.

Wafer handling system 260 can be configured to load and unload one or more wafers 302 to and from housing 220′″ of porous tool 200′″, for example, from a wafer cassette 274 (e.g., twenty-five wafers 302). Wafer handling system 260 can be further configured to process a wafer cassette 274 and provide automated large volume cassette-to-cassette processing (e.g., twenty-five wafers 302) to and from porous tool 200″′ to improve manufacturing efficiency and yield. As shown in FIG. 8, wafer handling system 260 can include load arm 262, heater 272, and wafer handling controller 270.

Load arm 262 can be configured to transfer a wafer 302 between porous tool 200″′ and wafer handling system 260. In some aspects, load arm 262 can include one or more actuators to translate wafer 302 to and from porous tool 200″′. For example, as shown in FIG. 8, load arm 262 can include an actuator 264 (e.g., linear servo motor) to translate wafer 302 from wafer handling system 260 into porous tool 200′″ in a loading step 266 and translate wafer 302 from porous tool 200′″ into wafer handling system 260 in an unloading step 268. In some aspects, load arm 262 can be configured to transfer one or more wafers 302 to and from heater 272. In some aspects, load arm 262 can be configured to transfer one or more wafers 302 to and from a wafer cassette 274.

Heater 272 can be configured to heat wafer 302 after a porosification process. As shown in FIG. 8, heater 272 can be coupled to wafer handling system 260. In some aspects, heater 272 can be coupled to porous tool 200″′. For example, heater 272 can be part of dryer 280 coupled to housing 220″′. One or more wafer cassettes 274 can be configured to provide automated large volume cassette-to-cassette processing (e.g., twenty-five wafers) to and from porous tool 200″′. In some aspects, a wafer cassette 274 can include a plurality of wafers 302. For example, a wafer cassette 274 can include twenty-five wafers 302. In some aspects, wafer handling system 260 can be configured to automatically process a wafer cassette 274 (e.g., twenty-five wafers 302).

Wafer handling controller 270 can be configured to control operations of load arm 262, heater 272, and a wafer cassette 274. As shown in FIG. 8, wafer handling controller 270 can be coupled to controller 250. In some aspects, wafer handling controller 270 can control a wafer 302 (e.g., from a wafer cassette 274) transfer into and out of wafer handling system 260. In some aspects, wafer handling controller 270 can send and receive signals to and from controller 250. For example, a feedback loop can be established between controller 250 and wafer handling controller 270 to control operations of wafer handling system 260. In some aspects, the feedback loop can use closed control or open control.

Controller 250 can be configured to control a loading and an unloading process of a wafer 302 to and from porous tool 200″′. As shown in FIG. 8, controller 250 can be coupled to wafer handling controller 270. In some aspects, controller 250 can control and monitor an entire wafer 302 processing, including loading a new wafer 302, processing the wafer 302, and unloading the porosified wafer 302 with porous layer 304. For example, controller 250 can establish a dynamic feedback loop between voltage source 230, first and second housing controllers 240a, 240b, dryer controller 282, and wafer handling controller 270. In some aspects, the dynamic feedback loop can use closed control or open control. In some aspects, controller 250 can implement a plurality of programmable steps (e.g., a recipe) for an entire wafer 302 processing. For example, controller 250 can implement up to a hundred programmable steps per recipe.

In some aspects, porous tool system 800 can be configured to load a wafer 302 within housing 220′″ via wafer handling system 260 (e.g., dry-in process). For example, as shown in FIG. 8, load arm 262 can transfer a wafer 302 into housing 220″′ of porous tool 200″′ in a loading step 266.

In some aspects, porous tool system 800 can be configured to seal a wafer 302 to housing 220′″ via first and second seals 221a′, 221b′. For example, as shown in FIG. 8, wafer 302 can be between first and second seals 221a′, 221b′ with first seal 221a′ sealing frontside 302a of wafer 302 and second seal 221b′ sealing backside 302 b of wafer 302.

In some aspects, porous tool system 800 can be configured to fill housing 220″′ with DI water via first and second input lines 242a, 242b prior to forming electrolytic cell 225. For example, first and second input lines 242a, 242b can flow DI water into housing 220″ prior to forming first and second electrolytes 222a, 222b, respectively.

In some aspects, porous tool system 800 can be configured to perform a leak check of the sealed housing 220″′ with wafer 302. For example, as shown in FIG. 8, first and second leak detectors 248a, 248b can check for any leaks (e.g., DI water) through first and second seals 221a′, 221b′, respectively.

In some aspects, porous tool system 800 can be configured to drain housing 220″′ of the DI water via first and second output lines 246a, 246b. For example, as shown in FIG. 8, first and second output lines 246a, 246b can flow the DI water out of housing 220″′ via first and second housing controllers 240a, 240b, respectively.

In some aspects, porous tool system 800 can be configured to fill housing 220″′ with an electrolyte solution via first and second input lines 242a, 242b. For example, first and second input lines 242a, 242b can flow buffered HF acid into housing 220″′ to form first and second electrolytes 222a, 222b (e.g., buffered HF acid), respectively. In some aspects, for example, first input line 242a can flow an acid solution into housing 220″′ to form first electrolyte 222a (e.g., buffered HF acid) and second input line 242b can flow a conductive solution into housing 220″′ to second electrolyte 222b (e.g., liquid Hg), respectively.

In some aspects, porous tool system 800 can be configured to perform a porosification process of a wafer 302. For example, as shown in FIG. 8, wafer 302 can be porosified by electrolytic cell 225 of porous tool 200″′ to form porous layer 304.

In some aspects, porous tool system 800 can be configured to, during porosification, hold a wafer 302 vertically within housing 220′″ (e.g., vertical configuration 10) such that only a first side of wafer 302 is porosified. For example, as shown in FIG. 5, housing 220′ can hold wafer 302 in vertical configuration 10 (e.g., vertically aligned) such that only frontside 302a of wafer 302 is porosified. In some aspects, only frontside 302a of wafer 302 can be porosified to form porous layer 304, for example, with first electrolyte 222a (e.g., 40% electrolyte concentration) having an electrolyte concentration greater than second electrolyte 222 b (e.g., 4% electrolyte concentration) thereby isolating porosification to only frontside 302a of wafer 302. In some aspects, housing 220′″ of porous tool 200′″ can be oriented 90° such that a central axis 284 of housing 220″′ is aligned along a horizontal axis (similar to housing 220′ shown in FIG. 5).

In some aspects, porous tool system 800 can be configured to, during porosification, control a current density per unit time (e.g., etch current density (mA/cm²)/etch time (s)) applied to electrolytic cell 225 via controller 250. For example, as shown in FIG. 8, a dynamic feedback loop can be established between voltage source 230 and controller 250 such that the current density per unit time can be monitored and adjusted by controller 250.

In some aspects, controller 250 can control concentrations of first and second electrolytes 222a, 222b applied to wafer 302 during a porosification process to form porous layer 304. For example, as shown in FIG. 8, a dynamic feedback loop can be established between first and second housing controllers 240a, 240b and controller 250 such that the concentrations (e.g., pH levels) can be monitored and adjusted by controller 250.

In some aspects, porous tool system 800 can be configured to, during porosification, monitor and adjust a current density per unit time (e.g., etch current density (mA/cm²)/etch time (s)) applied to wafer 302 in electrolytic cell 225 via a dynamic feedback loop between controller 250 and porous tool 200″′ (e.g., voltage source 230, first and second housing controllers 240a, 240b) based on a characteristic of porous layer 304. For example, the characteristic of porous layer 304 can include a porosification rate, a porosification depth, a porosity, a resistivity, a surface roughness, or a combination thereof.

In some aspects, porous tool system 800 can be configured to drain housing 220′″ of the electrolyte solution (e.g., buffered HF acid) via first and second output lines 246a, 246b. For example, as shown in FIG. 8, first and second output lines 246a, 246b can flow first and second electrolytes 222a, 222b (e.g., buffered HF acid) out of housing 220″′ via first and second housing controllers 240a, 240b, respectively.

In some aspects, porous tool system 800 can be configured to dilute an acid solution with DI water until the acid solution has a pH of about 7 (neutral) prior to draining housing 220″′ of the acid solution, thereby reducing hydrogen-terminated surfaces on wafer 302. For example, first and second input lines 242a, 242b can flow DI water into first and second electrolytes 222a, 222b (e.g., buffered HF acid) until a pH level of first and second electrolytes 222a, 222b, measured by first and second concentration detectors 244a, 244b, is about 7 (neutral), respectively.

In some aspects, porous tool system 800 can be configured to flush housing 220″′ with DI water via first and second input lines 242a, 242b prior to drying wafer 302 with porous layer 304. For example, first and second input lines 242a, 242b can flow DI water into housing 220′″ to flush frontside 302a and backside 302 b of wafer 302.

In some aspects, porous tool system 800 can be configured to add a floating layer of alcohol to an upper surface of the DI water prior to draining housing 220″′ of the DI water, thereby forming an alcohol coating on frontside 302a of wafer 302. For example, in horizontal configuration 30, first input line 242a can flow alcohol into the DI water until a floating layer of alcohol (e.g., due to different density) is formed on the upper surface of the DI water.

In some aspects, porous tool system 800 can be configured to drain housing 220″′ of the DI water via first and second output lines 246a, 246b. For example, as shown in FIG. 8, first and second output lines 246a, 246b can flow the DI water out of housing 220″′ via first and second housing controllers 240a, 240b, respectively. In some aspects, porous tool system 800 can be configured to drain housing 220′″ of the DI water with the floating layer of alcohol via first output line 246a. For example, first output line 246a can flow the DI water with the floating layer of alcohol out of housing 220″′ via first housing controller 240 a, thereby forming an alcohol coating on frontside 302a of wafer 302 and porous layer 304.

In some aspects, porous tool system 800 can be configured to dry wafer 302 within housing 220′″. For example, as shown in FIG. 8, dryer 280 can be coupled to housing 220″′ and can rotate wafer 302 about a central axis 284 in order to dry wafer 302 after a porosification process. In some aspects, porous tool system 800 can be configured to spin rinse dry wafer 302 within housing 220″′. For example, dryer 280 can include a spin rinse dryer. In some aspects, dryer controller 282 can be configured to control operations of dryer 280 and can send and receive signals to and from controller 250. For example, a feedback loop can be established between controller 250 and dryer controller 282 to control operations of dryer 280.

In some aspects, porous tool system 800 can be configured to unload a wafer 302 from housing 220″′ via wafer handling system 260 after porosification (e.g., dry-out process). For example, as shown in FIG. 8, load arm 262 can transfer wafer 302 out of housing 220′″ of porous tool 200′″ in an unloading step 268.

In some aspects, porous tool system 800 can be configured to heat a wafer 302. For example, as shown in FIG. 8, wafer handling system 260 can include heater 272 (e.g., hot plate, furnace, etc.) and can heat wafer 302 after a porosification process. In some aspects, wafer handling controller 270 can be configured to control operations of heater 272 and can send and receive signals to and from controller 250. For example, a feedback loop can be established between controller 250 and wafer handling controller 270 to control operations of heater 272.

In some aspects, porous tool system 800 can be configured to automatically process and porosify a cassette of wafers. For example, as shown in FIG. 8, porous tool system 800 can include porous tool 200″′ and wafer handling system 600, which can both be controlled and operated by controller 250 (e.g., via voltage source 230, first and second housing controllers 240a, 240b, wafer handling controller 270) to automatically process and porosify a wafer cassette 274 (e.g., twenty-five wafers 302).

### Exemplary Porous Layered Structures

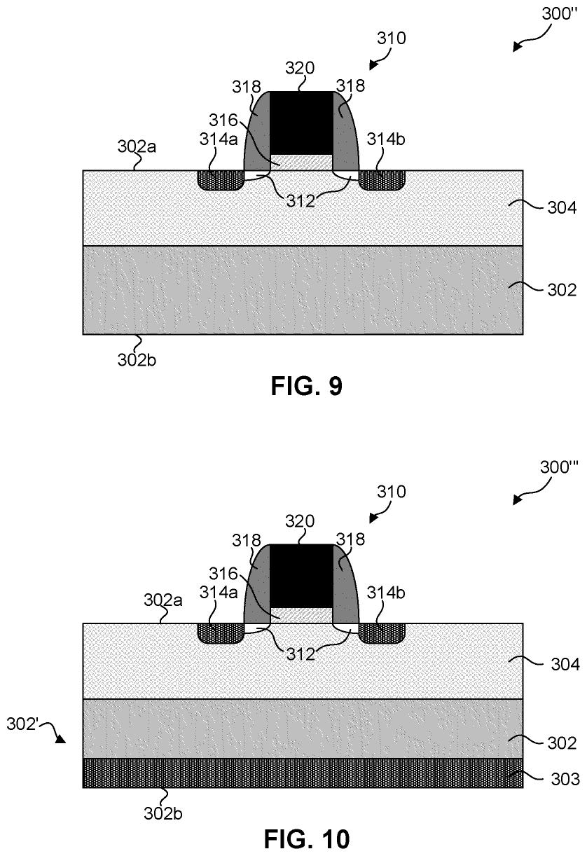

FIG. 9 illustrates porous layered structure 300″, according to an exemplary aspect. Porous layered structure 300″ increases a resistivity of porous layer 304 (e.g., greater than 5,000 Ω·cm), thereby decreasing harmonic losses in semiconductor device 310. Although porous layered structure 300″ is shown in FIG. 9 as a stand-alone apparatus and/or system, aspects of this disclosure can be used with other apparatuses, systems, and/or methods, for example, for example, dual bath porosification system 200′, porous tool 300″, porous tool 300″′, porous tool system 800, porous layered structure 300″, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

The aspects of porous layered structure 300 shown in FIG. 3A, for example, and the aspects of porous layered structure 300″ shown in FIG. 9 may be similar. Similar reference numbers are used to indicate features of the aspects of porous layered structure 300 shown in FIG. 3A and the similar features of the aspects of porous layered structure 300″ shown in FIG. 9.

As shown in FIG. 9, porous layered structure 300″ can include wafer 302 and porous layer 304. In some aspects, wafer 302 can include any suitable substrate having a predetermined crystallographic orientation, including but not limited to silicon, germanium, and III-V semiconductors. For example, wafer 302 can be a silicon wafer. In some aspects, wafer 302 can have a diameter of at least 200 mm. For example, wafer 302 can have a diameter of 300 mm.

In some aspects, porous layer 304 can have a higher resistivity than wafer 302. For example, porous layer 304 can have a resistivity of about 1,000 Ω·cm and wafer 302 can have a resistivity of about 1 Ω·cm. In some aspects, porous layer 304 can have a high resistivity (e.g., greater than about 5,000 Ω·cm) thereby decreasing harmonic losses. For example, porous layer 304 can suppress RF field lines from a device in or on porous layer 304, e.g., semiconductor device 310, from penetrating (bleeding) into wafer 302. In some aspects, porous layer 304 can have a thickness of at least 2 μm. For example, porous layer 304 can have a thickness of about 3 μm. In some aspects, porous layer 304 can have a thickness of at least 5 μm. For example, porous layer 304 can have a thickness of about 10 μm.

In some aspects, as shown in FIG. 9, porous layered structure 300″ can include semiconductor device 310 in porous layer 304. In some aspects, porous layered structure 300″ can include a semiconductor device on porous layer 304. In some aspects, semiconductor device 310 in or on porous layer 304 can include a passive device (e.g., an inductor, a filter, etc.). In some aspects, semiconductor device 310 in or on porous layer 304 can include an RF device (e.g., an RF inductor, an RF filter, etc.).

The aspects of porous layered structures 300″ shown in FIG. 9, for example, and the aspects of porous layered structure 300″′ shown in FIG. 10 may be similar. Similar reference numbers are used to indicate features of the aspects of porous layered structure 300″ shown in FIG. 9 and the similar features of the aspects of porous layered structures 300″′ shown in FIG. 10.

FIG. 10 illustrates porous layered structure 300″′ with modified substrate 302′, according to an exemplary aspect. Porous layered structure 300″ increases a resistivity of porous layer 304 (e.g., greater than 5,000 Ω·cm), thereby decreasing harmonic losses in semiconductor device 310. Although porous layered structure 300′″ is shown in FIG. 10 as a stand-alone apparatus and/or system, aspects of this disclosure can be used with other apparatuses, systems, and/or methods, for example, dual bath porosification system 200′, porous tool 300″, porous tool 300″′, porous tool system 800, porous layered structure 300″, porous layered structure 300″″, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

As shown in FIG. 10, porous layered structure 300″′ can include modified wafer 302′with backside conductive layer 303 and porous layer 304. Modified wafer 302′with backside conductive layer 303 can be configured to improve current flow through wafer 302, reduce electrolytic carrier depletion (e.g., diode depletion region) in wafer 302, and reduce metal contamination in porous layers 304. In some aspects, backside conductive layer 303 can be formed by ion implantation into wafer 302. In some aspects, backside conductive layer 303 can be formed by a spin on dopant (SOD) process, for example, a boron SOD process. In some aspects, backside conductive layer 303 can be formed by epitaxy on backside 302b of wafer 302.

In some aspects, backside conductive layer 303 can have a lower resistivity than wafer 302. For example, backside conductive layer 303 can have a resistivity of about 0.01 Ω·cm and wafer 302 can have a resistivity of about 1 Ω·cm. In some aspects, backside conductive layer 303 can have a resistivity no greater than about 0.01 Ω·cm. For example, backside conductive layer 303 can have a resistivity between about 1 m Ω·cm to about 0.01 Ω·cm.

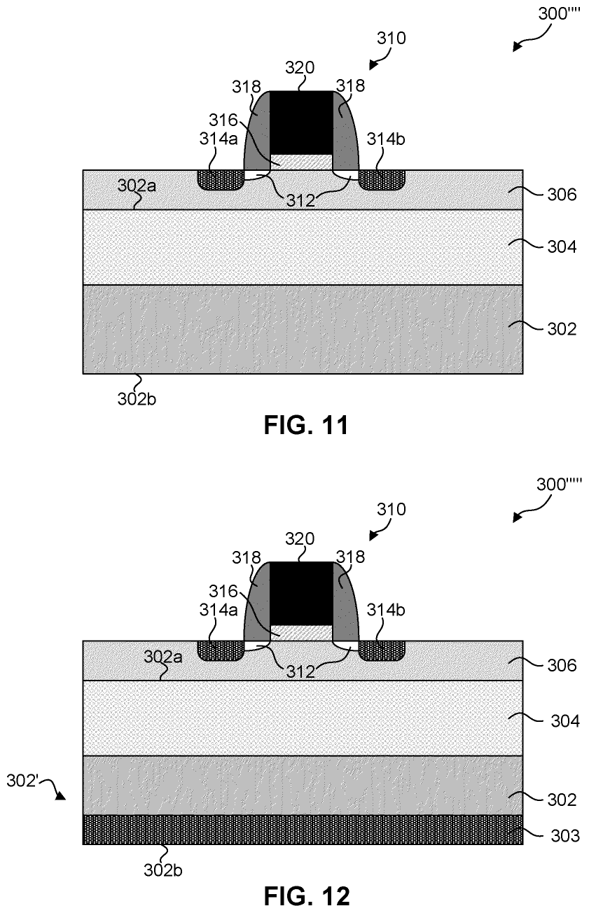

FIG. 11 illustrates porous layered structure 300″″, according to an exemplary aspect. Porous layered structure 300″″ increases a resistivity of porous layer 304 (e.g., greater than 5,000 Ω·cm), thereby decreasing harmonic losses in semiconductor device 310. Although porous layered structure 300″″ is shown in FIG. 11 as a stand-alone apparatus and/or system, aspects of this disclosure can be used with other apparatuses, systems, and/or methods, for example, for example, dual bath porosification system 200′, porous tool 300″, porous tool 300″′, porous tool system 800, porous layered structure 300″, porous layered structure 300″′, porous layered structure 300″″′, manufacturing diagram 1300, manufacturing diagram 1400, manufacturing diagram 1500, manufacturing diagram 1600, flow diagram 1700, flow diagram 1800, flow diagram 1900, and/or flow diagram 2000.

The aspects of porous layered structure 300 shown in FIG. 3A, for example, and the aspects of porous layered structure 300″″ shown in FIG. 11 may be similar. Similar reference numbers are used to indicate features of the aspects of porous layered structure 300 shown in FIG. 3A and the similar features of the aspects of porous layered structure 300″″ shown in FIG. 11.

As shown in FIG. 11, porous layered structure 300″″ can include wafer 302, porous layer 304, epilayer 306, and semiconductor device 310. In some aspects, wafer 302 can include any suitable substrate having a predetermined crystallographic orientation, including but not limited to silicon, germanium, and III-V semiconductors. For example, wafer 302 can be a silicon wafer. In some aspects, wafer 302 can have a diameter of at least 200 mm. For example, wafer 302 can have a diameter of 300 mm.

In some aspects, porous layer 304 can have a higher resistivity than wafer 302. For example, porous layer 304 can have a resistivity of about 1,000 Ω·cm and wafer 302 can have a resistivity of about 1 Ω·cm. In some aspects, porous layer 304 can have a high resistivity (e.g., greater than about 5,000 Ω·cm) thereby decreasing harmonic losses. For example, porous layer 304 can suppress RF field lines from semiconductor device 310 from penetrating (bleeding) into wafer 302. In some aspects, porous layer 304 can have a thickness of at least 2 μm. For example, porous layer 304 can have a thickness of about 3 μm. In some aspects, porous layer 304 can have a thickness of at least 5 μm. For example, porous layer 304 can have a thickness of about 10 μm.

The aspects of porous layered structures 300″″ shown in FIG. 11, for example, and the aspects of porous layered structure 300″″″ shown in FIG. 12 may be similar. Similar reference numbers are used to indicate features of the aspects of porous layered structure 300″″ shown in FIG. 11 and the similar features of the aspects of porous layered structures 300″″∝ shown in FIG. 12.

FIG. 12 illustrates porous layered structure 300″″′ with modified substrate 302′, according to an exemplary aspect. Porous layered structure 300″″′ increases a resistivity of porous layer 304 (e.g., greater than 5,000 Ω·cm), thereby decreasing harmonic losses in semiconductor device 310. Although porous layered structure 300″″′ is shown in FIG. 12 as a stand-alone apparatus and/or system, aspects of this disclosure can be used with other apparatuses, systems, and/or methods, for example, dual bath porosification system 200′, porous tool 300″, porous tool 300″′, porous tool system 800, porous layered structure 300″, porous layered structure 300″′, porous layered structure 300″″, manufacturing diagram 1300, manufacturing diagram 1400, manufacturing diagram 1500, manufacturing diagram 1600, flow diagram 1700, flow diagram 1800, flow diagram 1900, and/or flow diagram 2000.

As shown in FIG. 12, porous layered structure 300″″′ can include modified wafer 302′with backside conductive layer 303 and porous layer 304. Modified wafer 302′with backside conductive layer 303 can be configured to improve current flow through wafer 302, reduce electrolytic carrier depletion (e.g., diode depletion region) in wafer 302, and reduce metal contamination in porous layers 304. In some aspects, backside conductive layer 303 can be formed by ion implantation into wafer 302. In some aspects, backside conductive layer 303 can be formed by a spin on dopant (SOD) process, for example, a boron SOD process. In some aspects, backside conductive layer 303 can be formed by epitaxy on backside 302b of wafer 302.

In some aspects, backside conductive layer 303 can have a lower resistivity than wafer 302. For example, backside conductive layer 303 can have a resistivity of about 0.01 Ω·cm and wafer 302 can have a resistivity of about 1 Ω·cm. In some aspects, backside conductive layer 303 can have a resistivity no greater than about 0.01 Ω·cm. For example, backside conductive layer 303 can have a resistivity between about 1 m Ω·cm to about 0.01 Ω·cm.

### Exemplary Manufacturing Diagrams

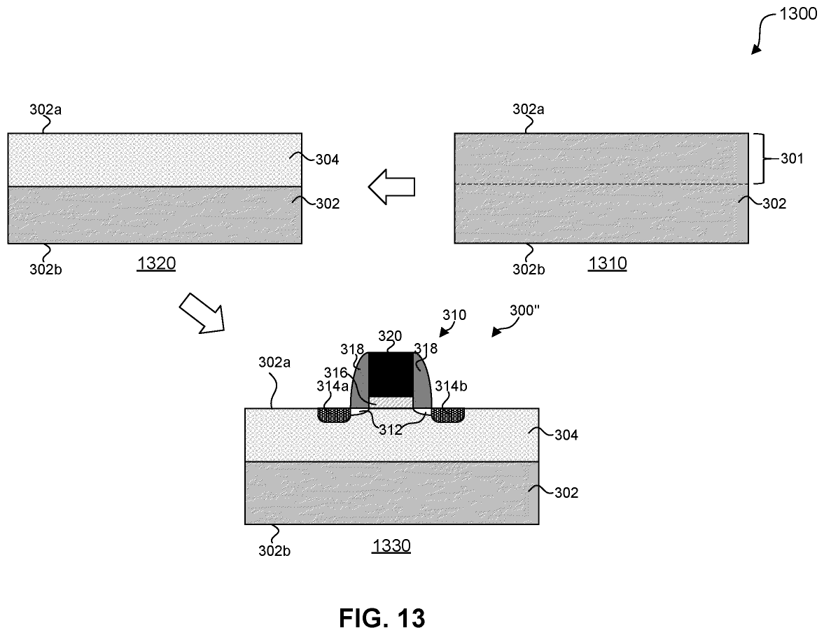

FIG. 13 illustrates manufacturing diagram 1300 for forming porous layered structure 300″, according to an exemplary aspect. It is to be appreciated that not all steps in FIG. 13 are needed to perform the disclosure provided herein. Further, some of the steps can be performed simultaneously, sequentially, and/or in a different order than shown in FIG. 13. Manufacturing diagram 1300 shall be described with reference to FIGS. 3A, 3B, and 5-9. However, manufacturing diagram 1300 is not limited to those example aspects.

As shown in FIG. 13, manufacturing diagram 1300 is configured to form porous layered structure 300″ shown in FIG. 9. In step 1310, a wafer 302 having a frontside 302a and a backside 302b is selected. In some aspects, wafer 302 can include any suitable substrate having a predetermined crystallographic orientation, including but not limited to silicon, germanium, and III-V semiconductors, for example, Si(100). In some aspects, wafer 302 can have a diameter of at least 200 mm, for example, a 300 mm silicon wafer. In some aspects, wafer 302 can have a diameter of about 200 mm. In some aspects, wafer 302 can have a diameter of about 300 mm. In some aspects, wafer 302 can have a diameter of about 450 mm.

In step 1320, a portion 301 of wafer 302 is porosified from frontside 302a towards backside 302b to form porous layer 304. In some aspects, wafer 302 can be porosified using porous tool 200″′ shown in FIG. 7. In some aspects, manufacturing diagram 1300 can further include annealing porous layer 304 after step 1320 but prior to step 1330. For example, porous layer 304 can be annealed at a temperature between about 300° C. to about 500° C. In some aspects, porous layer 304 can be annealed in heater 272 of wafer handling system 260 shown in FIG. 8.

In step 1330, a semiconductor device 310 is formed in or on porous layer 304 to form porous layered structure 300″. In some aspects, semiconductor device 310 can be a transistor (e.g., MOSFET) in a CMOS device, for example, an RF switch (e.g., RF switch 412 shown in FIG. 4). In some aspects, semiconductor device 310 can be a passive device (e.g., an inductor, a filter, etc.). In some aspects, semiconductor device 310 in or on porous layer can include a passive device (e.g., an inductor, a filter, etc.). In some aspects, semiconductor device 310 in or on porous layer 304 can include an RF device (e.g., an RF inductor, an RF filter, etc.). In some aspects, porous layered structure 300″ can omit semiconductor device 310 in or on porous layer 304, for example, as shown in step 1320 of FIG. 13.

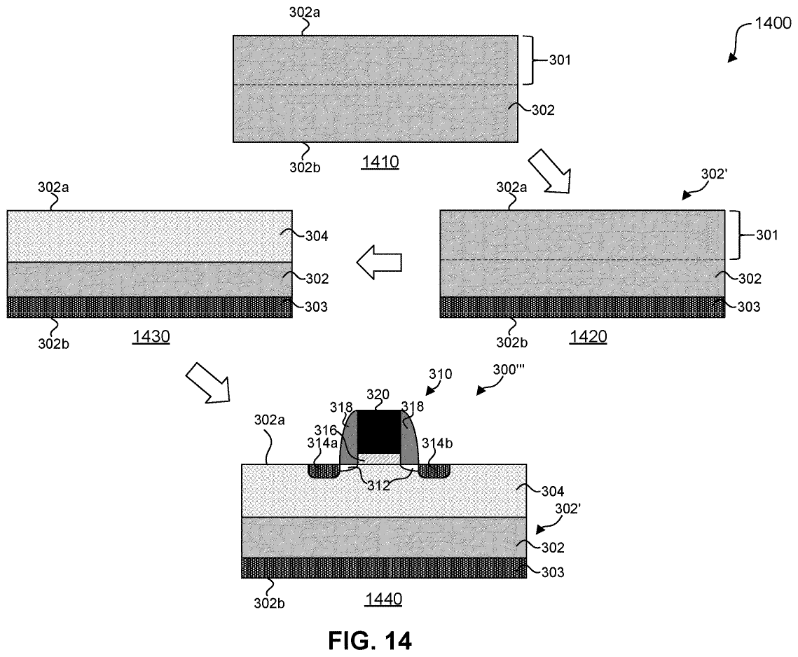

FIG. 14 illustrates manufacturing diagram 1400 for forming porous layered structure 300″′, according to an exemplary aspect. It is to be appreciated that not all steps in FIG. 14 are needed to perform the disclosure provided herein. Further, some of the steps can be performed simultaneously, sequentially, and/or in a different order than shown in FIG. 14. Manufacturing diagram 1400 shall be described with reference to FIGS. 5-8 and 10. However, manufacturing diagram 1400 is not limited to those example aspects.

As shown in FIG. 14, manufacturing diagram 1400 is configured to form porous layered structure 300″′ shown in FIG. 14. In step 1410, a wafer 302 having a frontside 302a and a backside 302b is selected. In some aspects, wafer 302 can include any suitable substrate having a predetermined crystallographic orientation, including but not limited to silicon, germanium, and III-V semiconductors, for example, Si(100). In some aspects, wafer 302 can have a diameter of at least 200 mm, for example, a 300 mm silicon wafer. In some aspects, wafer 302 can have a diameter of about 200 mm. In some aspects, wafer 302 can have a diameter of about 300 mm. In some aspects, wafer 302 can have a diameter of about 450 mm.

In step 1420, a backside conductive layer 303 is formed in backside 302b of wafer 302 to form modified wafer 302′. In some aspects, backside conductive layer 303 can be formed by ion implantation, a SOD process, or doped epitaxy.

In step 1430, a portion 301 of modified wafer 302′is porosified from frontside 302a towards backside 302b to form porous layer 304. In some aspects, modified wafer 302′can be porosified using porous tool 200″′ shown in FIG. 7. In some aspects, manufacturing diagram 1400 can further include annealing porous layer 304 after step 1430 but prior to step 1440. For example, porous layer 304 can be annealed at a temperature between about 300 ° C. to about 500° C. In some aspects, porous layer 304 can be annealed in heater 272 of wafer handling system 260 shown in FIG. 8.

In step 1440, a semiconductor device 310 is formed in or on porous layer 304 to form porous layered structure 300″′. In some aspects, semiconductor device 310 can be a transistor (e.g., MOSFET) in a CMOS device, for example, an RF switch (e.g., RF switch 412 shown in FIG. 4). In some aspects, semiconductor device 310 can be a passive device (e.g., an inductor, a filter, etc.). In some aspects, semiconductor device 310 in or on porous layer can include a passive device (e.g., an inductor, a filter, etc.). In some aspects, semiconductor device 310 in or on porous layer 304 can include an RF device (e.g., an RF inductor, an RF filter, etc.). In some aspects, porous layered structure 300″∝ can omit semiconductor device 310 in or one porous layer 304, for example, as shown in step 1430 of FIG. 14.

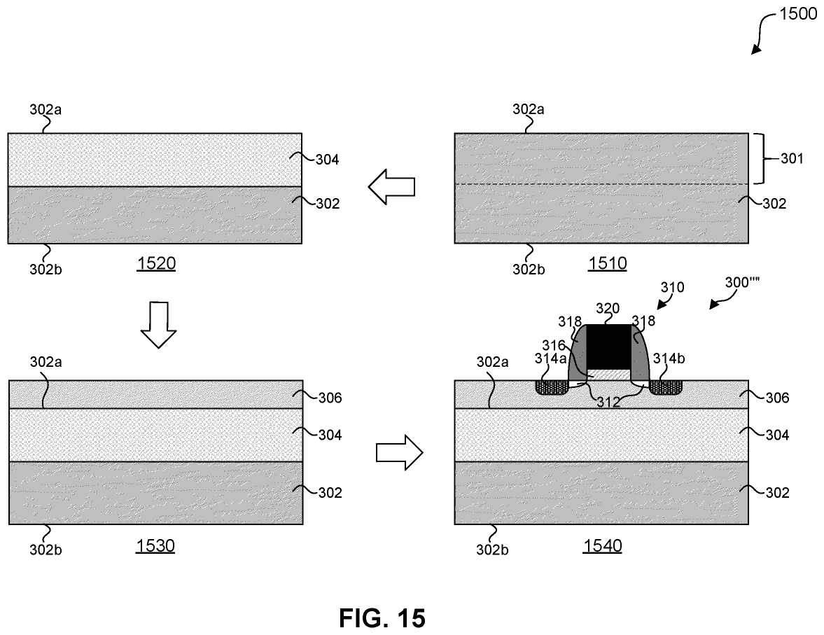

FIG. 15 illustrates manufacturing diagram 1500 for forming porous layered structure 300″, according to an exemplary aspect. It is to be appreciated that not all steps in FIG. 15 are needed to perform the disclosure provided herein. Further, some of the steps can be performed simultaneously, sequentially, and/or in a different order than shown in FIG. 15. Manufacturing diagram 1500 shall be described with reference to FIGS. 3A, 3B, 5-8, and 11. However, manufacturing diagram 1500 is not limited to those example aspects.

As shown in FIG. 15, manufacturing diagram 1500 is configured to form porous layered structure 300″″ shown in FIG. 11. In some aspects, manufacturing diagram 1500 is configured to form porous layered structures 300, 300′shown in FIGS. 3A and 3B, respectively. In step 1510, a wafer 302 having a frontside 302a and a backside 302b is selected. In some aspects, wafer 302 can include any suitable substrate having a predetermined crystallographic orientation, including but not limited to silicon, germanium, and III-V semiconductors, for example, Si(100). In some aspects, wafer 302 can have a diameter of at least 200 mm, for example, a 300 mm silicon wafer. In some aspects, wafer 302 can have a diameter of about 200 mm. In some aspects, wafer 302 can have a diameter of about 300 mm. In some aspects, wafer 302 can have a diameter of about 450 mm.

In step 1520, a portion 301 of wafer 302 is porosified from frontside 302a towards backside 302b to form porous layer 304. In some aspects, wafer 302 can be porosified using porous tool 200′″ shown in FIG. 7. In some aspects, manufacturing diagram 1500 can further include annealing porous layer 304 after step 1520 but prior to step 1530. For example, porous layer 304 can be annealed at a temperature between about 300° C. to about 500° C. In some aspects, porous layer 304 can be annealed in heater 272 of wafer handling system 260 shown in FIG. 8.

In step 1530, an epilayer 306 is grown over porous layer 304 (e.g., on frontside). In some aspects, epilayer 306 can include any suitable epilayer having a predetermined crystallographic orientation, including but not limited to silicon, germanium, Group IV semiconductors, and III-V semiconductors. In some aspects, epilayer 306 can be a defect-free, single crystal epilayer formed directly atop porous layer 304.

In step 1540, a semiconductor device 310 is formed in epilayer 306 to form porous layered structure 300″″. In some aspects, semiconductor device 310 can be a transistor (e.g., MOSFET) in a CMOS device, for example, an RF switch (e.g., RF switch 412 shown in FIG. 4). In some aspects, semiconductor device 310 can be a passive device (e.g., an inductor, a filter, etc.). In some aspects, manufacturing diagram 1500 can be used to form porous layered structure 300 with wafer 302 shown in FIG. 3A. In some aspects, manufacturing diagram 1500 can be used to form porous layered structure 300′ with wafer 302 shown in FIG. 3B.

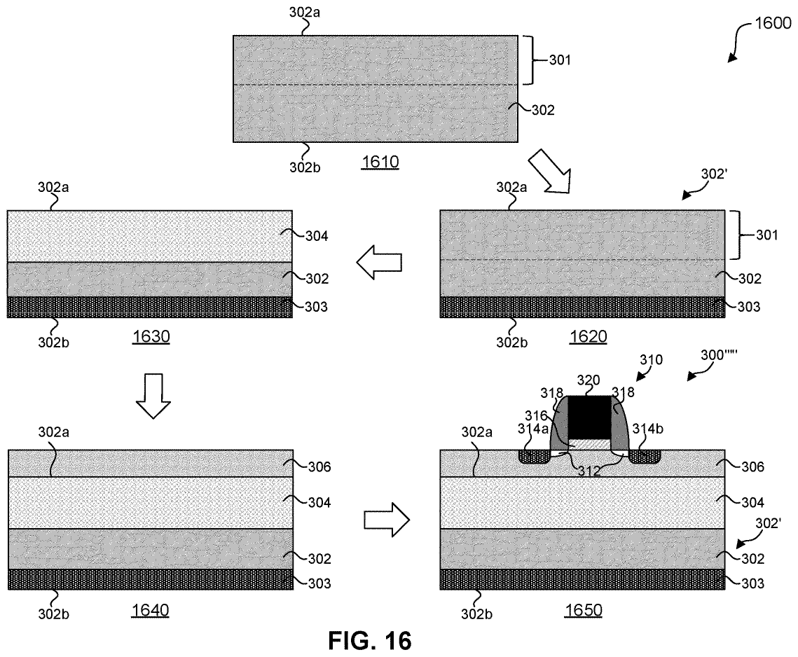

FIG. 16 illustrates manufacturing diagram 1600 for forming porous layered structure 300″″′, according to an exemplary aspect. It is to be appreciated that not all steps in FIG. 16 are needed to perform the disclosure provided herein. Further, some of the steps can be performed simultaneously, sequentially, and/or in a different order than shown in FIG. 16. Manufacturing diagram 1600 shall be described with reference to FIGS. 5-8 and 12. However, manufacturing diagram 1600 is not limited to those example aspects.

As shown in FIG. 16, manufacturing diagram 1600 is configured to form porous layered structure 300″″′ shown in FIG. 12. In step 1610, a wafer 302 having a frontside 302a and a backside 302 b is selected. In some aspects, wafer 302 can include any suitable substrate having a predetermined crystallographic orientation, including but not limited to silicon, germanium, and III-V semiconductors, for example, Si(100). In some aspects, wafer 302 can have a diameter of at least 200 mm, for example, a 300 mm silicon wafer. In some aspects, wafer 302 can have a diameter of about 200 mm. In some aspects, wafer 302 can have a diameter of about 300 mm. In some aspects, wafer 302 can have a diameter of about 450 mm.

In step 1620, a backside conductive layer 303 is formed in backside 302b of wafer 302 to form modified wafer 302′. In some aspects, backside conductive layer 303 can be formed by ion implantation, a SOD process, or doped epitaxy.

In step 1630, a portion 301 of modified wafer 302′ is porosified from frontside 302a towards backside 302b to form porous layer 304. In some aspects, modified wafer 302′ can be porosified using porous tool 200″′ shown in FIG. 7. In some aspects, manufacturing diagram 1600 can further include annealing porous layer 304 after step 1630 but prior to step 1640. For example, porous layer 304 can be annealed at a temperature between about 300° C. to about 500° C. In some aspects, porous layer 304 can be annealed in heater 272 of wafer handling system 260 shown in FIG. 8.

In step 1640, an epilayer 306 is grown over porous layer 304 (e.g., on frontside). In some aspects, epilayer 306 can include any suitable epilayer having a predetermined crystallographic orientation, including but not limited to silicon, germanium, Group IV semiconductors, and III-V semiconductors. In some aspects, epilayer 306 can be a defect-free, single crystal epilayer formed directly atop porous layer 304.

In step 1650, a semiconductor device 310 is formed in epilayer 306 to form porous layered structure 300″″′. In some aspects, semiconductor device 310 can be a transistor (e.g., MOSFET) in a CMOS device, for example, an RF switch (e.g., RF switch 412 shown in FIG. 4). In some aspects, semiconductor device 310 can be a passive device (e.g., an inductor, a filter, etc.).

### Exemplary Flow Diagrams

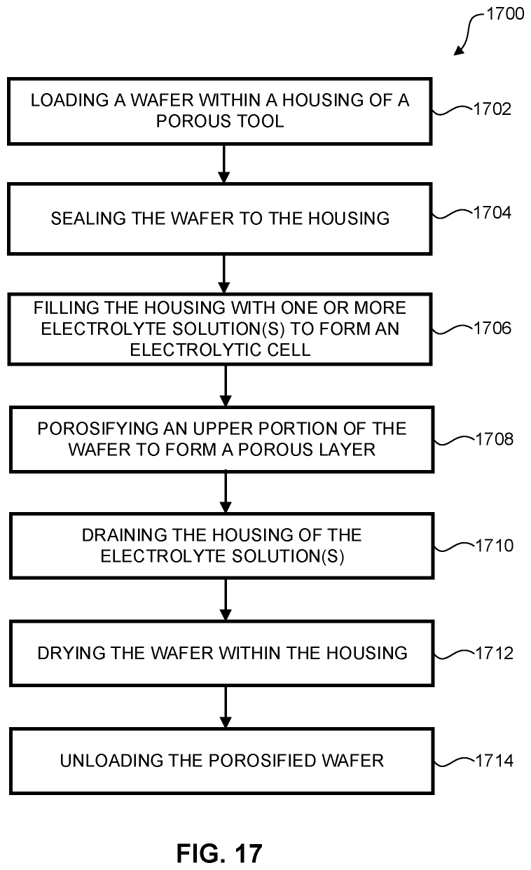

FIG. 17 illustrates flow diagram 1700 to describe the process of forming porous layered structures 300″, 300″, 300″″, 300″″′ using a dry-in and dry-out wafer porosification process (e.g., porous tool 200″ shown in FIG. 6, porous tool 200″′ shown in FIG. 7, porous tool system 800 shown in FIG. 8), according to an exemplary aspect. It is to be appreciated that not all steps in FIG. 17 are needed to perform the disclosure provided herein. Further, some of the steps can be performed simultaneously, sequentially, and/or in a different order than shown in FIG. 17. Flow diagram 1700 shall be described with reference to FIGS. 5-16. However, flow diagram 1700 is not limited to those example aspects.

As shown in FIG. 17, flow diagram 1700 describes a dry-in and dry-out wafer porosification process to form porous layered structures 300″, 300″, 300″″, 300″″′ shown in FIGS. 9-12. In step 1702, as shown in the examples of FIGS. 5-8, a wafer 302 is loaded into housing 220″, 220′″ of porous tool 200″, 200″′, respectively (e.g., dry-in process). In some aspects, wafer 302 is loaded into housing 220″, 220′″ of porous tool 200″, 200′″ via wafer handling system 260. For example, as shown in FIG. 8, load arm 262 can transfer wafer 302 into housing 220′″ of porous tool 200′″ in a loading step 266.

In step 1704, as shown in the examples of FIGS. 5-8, wafer 302 is sealed to housing 220″, 220″′. In some aspects, wafer 302 is sealed to housing 220″, 220′″ via seal 221 or via first and second seals 221a', 221b', respectively. For example, as shown in FIG. 8, wafer 302 can be between first and second seals 221a', 221b′ with first seal 221a′ sealing frontside 302a of wafer 302 and second seal 221 b′ sealing backside 302 b of wafer 302.

In step 1706, as shown in the examples of FIGS. 5-8, housing 220″, 220″′ is filled with one or more electrolyte solution(s) to form electrolytic cell 225. In some aspects, housing 220″, 220′″ is filled with an electrolyte solution (e.g., buffered HF acid) via input line 242 or first and second input lines 242a, 242b, respectively. For example, first and second input lines 242a, 242b can flow buffered HF acid into housing 220″′ to form first and second electrolytes 222a, 222b (e.g., buffered HF acid), respectively. In some aspects, housing 220″, 220″′ is filled with one or more electrolyte solutions (e.g., buffered HF acid) via input line 242 or first and second input lines 242a, 242b, respectively. For example, first input line 242a can flow a first buffered HF acid into housing 220″′ to form first electrolyte 222 a (e.g., 40% concentration buffered HF acid) and second input line 242 b can flow a second buffered HF acid into housing 220′″ to form second electrolyte 222b (e.g., 4% concentration buffered HF acid), respectively. In some aspects, first input line 242 a can flow an acid solution to form first electrolyte 222a and second input line 242b can flow a conductive solution to form second electrolyte 222b. For example, first electrolyte 222a can include buffered HF acid and second electrolyte 222b can include liquid Hg.

In step 1708, as shown in the examples of FIGS. 5-8 and 13-16, a portion 301 of wafer 302 is porosified to form porous layer 304. In some aspects, wafer 302 can be porosified by electrolytic cell 225 of porous tool 200″, 200′″ to form porous layer 304. In some aspects, a current density per unit time (e.g., etch current density (mA/cm²)/etch time (s)) applied to electrolytic cell 225 during porosification can be controlled via controller 250. For example, as shown in FIG. 8, a dynamic feedback loop can be established between voltage source 230 and controller 250 such that the current density per unit time can be monitored and adjusted by controller 250.

In step 1710, as shown in the examples of FIGS. 5-8, housing 220″, 220″′ is drained of the electrolyte solution(s) (e.g., buffered HF acid). In some aspects, the electrolyte solution(s) can be drained from housing 220″, 220′″ via output line 246 or first and second output lines 246a, 246b, respectively. For example, as shown in FIG. 8, first and second output lines 246a, 246b can flow first and second electrolytes 222a, 222b (e.g., buffered HF acid) out of housing 220′″ via first and second housing controllers 240a, 240b, respectively.

In step 1712, as shown in the examples of FIGS. 5-8, wafer 302 can be dried within housing 220″, 220″′. In some aspects, a dryer can be coupled to housing 220″, 220″′. For example, as shown in FIG. 8, dryer 280 (e.g., a spin rinse dryer, a hot plate, a furnace, an oven, an annealer, etc.) can be coupled to housing 220′″. In some aspects, dryer 280 can include a spin rinse dryer. For example, dryer 280 can rotate wafer 302 about a central axis 284 in order to dry wafer 302 after a porosification process. In some aspects, the spin rinse dryer (e.g., dryer 280 shown in FIG. 8) can spin the wafer 302 while spraying the wafer 302 with an inert gas (e.g., nitrogen (N), argon (Ar), etc.) and/or another chemical (e.g., DI water) to dry the whole wafer 302 (e.g., via centrifugal forces and/or heated inert gas). In some aspects, dryer 280 can include a hot plate, a furnace, or an oven for a long duration bake. In some aspects, dryer 280 can include an annealer (e.g., flash lamp annealer) for a short duration bake (e.g., rapid thermal anneal).

In step 1714, as shown in the examples of FIGS. 5-8, wafer 302 with porous layer 304 is unloaded from housing 220″, 220′″ of porous tool 200″, 200″′, respectively (e.g., dry-out process). In some aspects, wafer 302 is unloaded from housing 220″, 220″′ of porous tool 200″, 200′″ via wafer handling system 260. For example, as shown in FIG. 8, load arm 262 can transfer wafer 302 out of housing 220′″ of porous tool 200′″ in an unloading step 268.

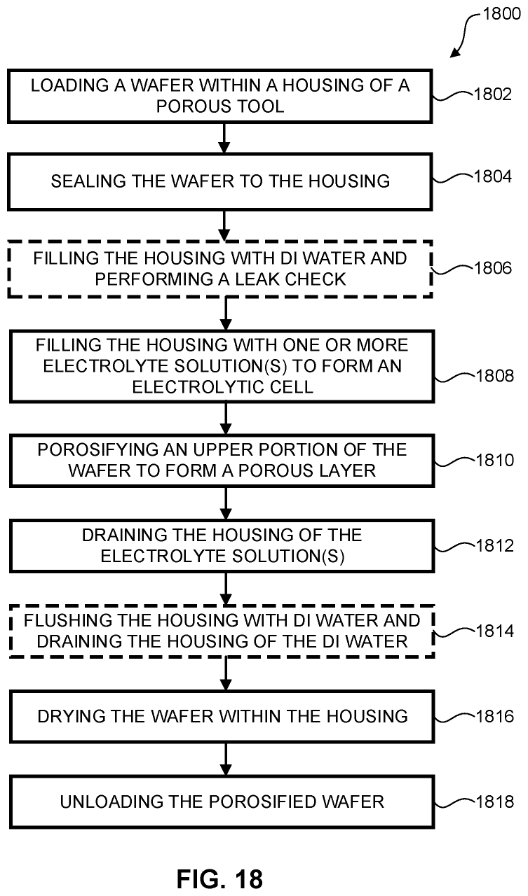

The aspects of flow diagram 1700 shown in FIG. 17, for example, and the aspects of flow diagram 1800 shown in FIG. 18 may be similar. Similar reference numbers are used to indicate features of the aspects of flow diagram 1700 shown in FIG. 17 and the similar features of the aspects of flow diagram 1800 shown in FIG. 18.

FIG. 18 illustrates flow diagram 1800 to describe the process of forming porous layered structures 300″, 300″′, 300″″, 300″″′ using a dry-in and dry-out wafer porosification process (e.g., porous tool 200″ shown in FIG. 6, porous tool 200″′ shown in FIG. 7, porous tool system 800 shown in FIG. 8), according to an exemplary aspect. It is to be appreciated that not all steps in FIG. 18 are needed to perform the disclosure provided herein. Further, some of the steps can be performed simultaneously, sequentially, and/or in a different order than shown in FIG. 18. Flow diagram 1800 shall be described with reference to FIGS. 5-16. However, flow diagram 1800 is not limited to those example aspects.

As shown in FIG. 18, flow diagram 1800 describes a dry-in and dry-out wafer porosification process to form porous layered structures 300″, 300″′, 300″″, 300″″′ shown in FIGS. 9-12. In step 1802, as shown in the examples of FIGS. 5-8, a wafer 302 is loaded into housing 220″, 220′″ of porous tool 200″, 200′″, respectively (e.g., dry-in process). In some aspects, wafer 302 is loaded into housing 220″, 220″′ of porous tool 200″, 200″′ via wafer handling system 260. For example, as shown in FIG. 8, load arm 262 can transfer wafer 302 into housing 220′″ of porous tool 200″′ in a loading step 266.

In step 1804, as shown in the examples of FIGS. 5-8, wafer 302 is sealed to housing 220″, 220″′. In some aspects, wafer 302 is sealed to housing 220″, 220′″ via seal 221 or via first and second seals 221a′, 221b′, respectively. For example, as shown in FIG. 8, wafer 302 can be between first and second seals 221a′, 221b′ with first seal 221a′ sealing frontside 302a of wafer 302 and second seal 221 b′ sealing backside 302b of wafer 302.

In step 1806, as shown in the examples of FIGS. 5-8, housing 220″, 220″′ is filled with DI water to perform a leak check. In some aspects, a leak check of the DI filled housing 220″, 220′″ can be performed by leak detector 248 or first and second leak detectors 248a, 248b, respectively. For example, as shown in FIG. 8, first and second leak detectors 248a, 248b can check for any leaks from the DI water through first and second seals 221a′, 221b′, respectively. In some aspects, the DI water may be drained via output line 246 or first and second output lines 246a, 246b prior to step 1808. In some aspects, step 1806 is optional and can be omitted from flow diagram 1800. In some aspects, step 1806 can be added to flow diagram 1700 between step 1704 and step 1706 shown in FIG. 17.

In step 1808, as shown in the examples of FIGS. 5-8, housing 220″, 220′″ is filled with one or more electrolyte solution(s) to form electrolytic cell 225. In some aspects, housing 220″, 220″′ is filled an electrolyte solution (e.g., buffered HF acid) via input line 242 or first and second input lines 242a, 242b, respectively. For example, first and second input lines 242a, 242b can flow buffered HF acid into housing 220″ to form first and second electrolytes 222a, 222b (e.g., buffered HF acid), respectively. In some aspects, housing 220″, 220′″ is filled with one or more electrolyte solutions (e.g., buffered HF acid) via input line 242 or first and second input lines 242a, 242b, respectively. For example, first input line 242a can flow a first buffered HF acid into housing 220″′ to form first electrolyte 222 a (e.g., 40% concentration buffered HF acid) and second input line 242 b can flow a second buffered HF acid into housing 220″′ to form second electrolyte 222b (e.g., 4% concentration buffered HF acid), respectively. In some aspects, first input line 242 a can flow an acid solution to form first electrolyte 222a and second input line 242b can flow a conductive solution to form second electrolyte 222b. For example, first electrolyte 222a can include buffered HF acid and second electrolyte 222b can include liquid Hg.

In step 1810, as shown in the examples of FIGS. 5-8 and 12-16, a portion 301 of wafer 302 is porosified to form porous layer 304. In some aspects, wafer 302 can be porosified by electrolytic cell 225 of porous tool 200″, 200′″ to form porous layer 304. In some aspects, a current density per unit time (e.g., etch current density (mA/cm²)/etch time (s)) applied to electrolytic cell 225 during porosification can be controlled via controller 250. For example, as shown in FIG. 8, a dynamic feedback loop can be established between voltage source 230 and controller 250 such that the current density per unit time can be monitored and adjusted by controller 250.

In step 1812, as shown in the examples of FIGS. 5-8, housing 220″, 220′″ is drained of the electrolyte solution(s) (e.g., buffered HF acid). In some aspects, the electrolyte solution(s) can be drained from housing 220″, 220′″ via output line 246 or first and second output lines 246a, 246b, respectively. For example, as shown in FIG. 8, first and second output lines 246a, 246b can flow first and second electrolytes 222a, 222b (e.g., buffered HF acid) out of housing 220′″ via first and second housing controllers 240a, 240b, respectively.

In step 1814, as shown in the examples of FIGS. 5-8, housing 220″, 220″′ is flushed with DI water and then housing 220″, 220″′ is drained of the DI water. In some aspects, housing 220″, 220″′ can be flushed with DI water via input line 242 or first and second input lines 242a, 242b. For example, first and second input lines 242a, 242b can flow DI water into housing 220′″ to flush frontside 302a and backside 302b of wafer 302. In some aspects, housing 220″, 220′″ can be drained of the DI water via output line 246 or first and second output lines 246a, 246b. For example, as shown in FIG. 8, first and second output lines 246a, 246b can flow the DI water out of housing 220′″ via first and second housing controllers 240a, 240b, respectively. In some aspects, step 1814 is optional and can be omitted from flow diagram 1800. In some aspects, step 1814 can be added to flow diagram 1700 between step 1710 and step 1712 shown in FIG. 17.

In step 1816, as shown in the examples of FIGS. 5-8, wafer 302 can be dried within housing 220″, 220″′. In some aspects, a dryer can be coupled to housing 220″, 220″′. For example, as shown in FIG. 8, dryer 280 (e.g., a spin rinse dryer, a hot plate, a furnace, an oven, an annealer, etc.) can be coupled to housing 220″′. In some aspects, dryer 280 can include a spin rinse dryer. For example, dryer 280 can rotate wafer 302 about a central axis 284 in order to dry wafer 302 after a porosification process. In some aspects, the spin rinse dryer (e.g., dryer 280 shown in FIG. 8) can spin the wafer 302 while spraying the wafer 302 with an inert gas (e.g., N, Ar, etc.) and/or another chemical (e.g., DI water) to dry the whole wafer 302 (e.g., via centrifugal forces and/or heated inert gas). In some aspects, dryer 280 can include a hot plate, a furnace, or an oven for a long duration bake. In some aspects, dryer 280 can include an annealer (e.g., flash lamp annealer) for a short duration bake (e.g., rapid thermal anneal).

In step 1818, as shown in the examples of FIGS. 5-8, wafer 302 with porous layer 304 is unloaded from housing 220″, 220′″ of porous tool 200″, 200″′, respectively (e.g., dry-out process). In some aspects, wafer 302 is unloaded from housing 220″, 220″′ of porous tool 200″, 200′″ via wafer handling system 260. For example, as shown in FIG. 8, load arm 262 can transfer wafer 302 out of housing 220′″ of porous tool 200′″ in an unloading step 268.

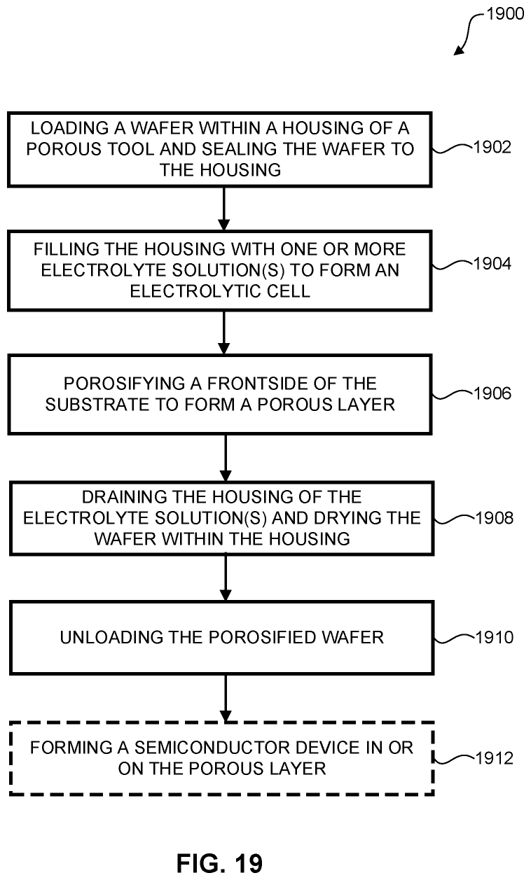

The aspects of flow diagram 1700 shown in FIG. 17, for example, and the aspects of flow diagram 1900 shown in FIG. 19 may be similar. Similar reference numbers are used to indicate features of the aspects of flow diagram 1700 shown in FIG. 17 and the similar features of the aspects of flow diagram 1900 shown in FIG. 19.

FIG. 19 illustrates flow diagram 1900 to describe the process of forming porous layered structures 300″, 300″′ using a dry-in and dry-out wafer porosification process (e.g., porous tool 200″ shown in FIG. 6, porous tool 200″′ shown in FIG. 7, porous tool system 800 shown in FIG. 8), according to an exemplary aspect. It is to be appreciated that not all steps in FIG. 19 are needed to perform the disclosure provided herein. Further, some of the steps can be performed simultaneously, sequentially, and/or in a different order than shown in FIG. 19. Flow diagram 1900 shall be described with reference to FIGS. 5-10, 13, and 14. However, flow diagram 1900 is not limited to those example aspects.

As shown in FIG. 19, flow diagram 1900 describes a dry-in and dry-out wafer porosification process to form porous layered structures 300″, 300″′ shown in FIGS. 9 and 10, respectively. In step 1902, as shown in the examples of FIGS. 5-8, a wafer 302 is loaded into housing 220″, 220′″ of porous tool 200″, 200″′ and sealed to housing 220″, 220″, respectively (e.g., dry-in process). In some aspects, wafer 302 is loaded into housing 220″, 220′″ of porous tool 200″, 200″′ via wafer handling system 260. For example, as shown in FIG. 8, load arm 262 can transfer a wafer 302 into housing 220′″ of porous tool 200′″ in a loading step 266. In some aspects, wafer 302 is sealed to housing 220″, 220′″ via seal 221 or via first and second seals 221a', 221b′, respectively. For example, as shown in FIG. 8, wafer 302 can be between first and second seals 221a′, 221b′ with first seal 221a′ sealing frontside 302a of wafer 302 and second seal 221 b′ sealing backside 302 b of wafer 302.

In step 1904, as shown in the examples of FIGS. 5-8, housing 220″, 220′″ is filled with one or more electrolyte solution(s) to form electrolytic cell 225. In some aspects, housing 220″, 220′″ is filled an electrolyte solution (e.g., buffered HF acid) via input line 242 or first and second input lines 242a, 242b, respectively. For example, first and second input lines 242a, 242b can flow buffered HF acid into housing 220″′ to form first and second electrolytes 222a, 222b (e.g., buffered HF acid), respectively. In some aspects, housing 220″, 220′″ is filled with one or more electrolyte solutions (e.g., buffered HF acid) via input line 242 or first and second input lines 242a, 242b, respectively. For example, first input line 242a can flow a first buffered HF acid into housing 220″′ to form first electrolyte 222 a (e.g., 40% concentration buffered HF acid) and second input line 242 b can flow a second buffered HF acid into housing 220″′ to form second electrolyte 222b (e.g., 4% concentration buffered HF acid), respectively. In some aspects, first input line 242 a can flow an acid solution to form first electrolyte 222a and second input line 242b can flow a conductive solution to form second electrolyte 222b. For example, first electrolyte 222a can include buffered HF acid and second electrolyte 222b can include liquid Hg.

In step 1906, as shown in the examples of FIGS. 5-8, 13, and 14, frontside 302a of wafer 302 is porosified to form porous layer 304. In some aspects, wafer 302 can be porosified by electrolytic cell 225 of porous tool 200″, 200″′ to form porous layer 304. In some aspects, a current density per unit time (e.g., etch current density (mA/cm²)/etch time (s)) applied to electrolytic cell 225 during porosification can be controlled via controller 250. For example, as shown in FIG. 8, a dynamic feedback loop can be established between voltage source 230 and controller 250 such that the current density per unit time can be monitored and adjusted by controller 250.

In step 1908, as shown in the examples of FIGS. 5-8, housing 220″, 220″′ is drained of the electrolyte solution(s) (e.g., buffered HF acid) and wafer 302 is dried within housing 220″, 220″′. In some aspects, the electrolyte solution(s) can be drained from housing 220″, 220″′ via output line 246 or first and second output lines 246a, 246b, respectively. For example, as shown in FIG. 8, first and second output lines 246a, 246b can flow first and second electrolytes 222a, 222b (e.g., buffered HF acid) out of housing 220′″ via first and second housing controllers 240a, 240b, respectively. In some aspects, a dryer can be coupled to housing 220″, 220″′. For example, as shown in FIG. 8, dryer 280 (e.g., a spin rinse dryer, a hot plate, a furnace, an oven, an annealer, etc.) can be coupled to housing 220′″. In some aspects, dryer 280 can include a spin rinse dryer. For example, dryer 280 can rotate wafer 302 about a central axis 284 in order to dry wafer 302 after a porosification process. In some aspects, the spin rinse dryer (e.g., dryer 280 shown in FIG. 8) can spin the wafer 302 while spraying the wafer 302 with an inert gas (e.g., N, Ar, etc.) and/or another chemical (e.g., DI water) to dry the whole wafer 302 (e.g., via centrifugal forces and/or heated inert gas). In some aspects, dryer 280 can include a hot plate, a furnace, or an oven for a long duration bake. In some aspects, dryer 280 can include an annealer (e.g., flash lamp annealer) for a short duration bake (e.g., rapid thermal anneal).

In step 1910, as shown in the examples of FIGS. 5-8, 13, and 14, wafer 302 with porous layer 304 is unloaded from housing 220″, 220″′ of porous tool 200″, 200″′, respectively (e.g., dry-out process). In some aspects, wafer 302 is unloaded from housing 220″, 220′″ of porous tool 200″, 200″′ via wafer handling system 260. For example, as shown in FIG. 8, load arm 262 can transfer wafer 302 out of housing 220′″ of porous tool 200″′ in an unloading step 268. In some aspects, wafer 302 with porous layer 304 can be annealed prior to a device fabrication process. For example, as shown in FIG. 8, wafer 302 can be annealed in heater 272 of wafer handling system 260 prior to forming a semiconductor device 310.

In step 1912, as shown in the examples of FIGS. 9 and 10, a semiconductor device 310 is formed in or on porous layer 304 to form porous layered structure 300″, 300″′. In some aspects, porous layered structure 300″, 300′″ can include semiconductor device 310 in porous layer 304. In some aspects, porous layered structure 300″, 300″′ can include a semiconductor device on porous layer 304. In some aspects, semiconductor device 310 in or on porous layer 304 can include a passive device (e.g., an inductor, a filter, etc.). In some aspects, semiconductor device 310 in or on porous layer 304 can include an RF device (e.g., an RF inductor, an RF filter, etc.). In some aspects, a plurality of semiconductor devices can be formed in or on porous layer 304. For example, as shown in FIG. 3B, a plurality of semiconductor devices 310a, 310b, 310c can be formed in or on porous layer 304.

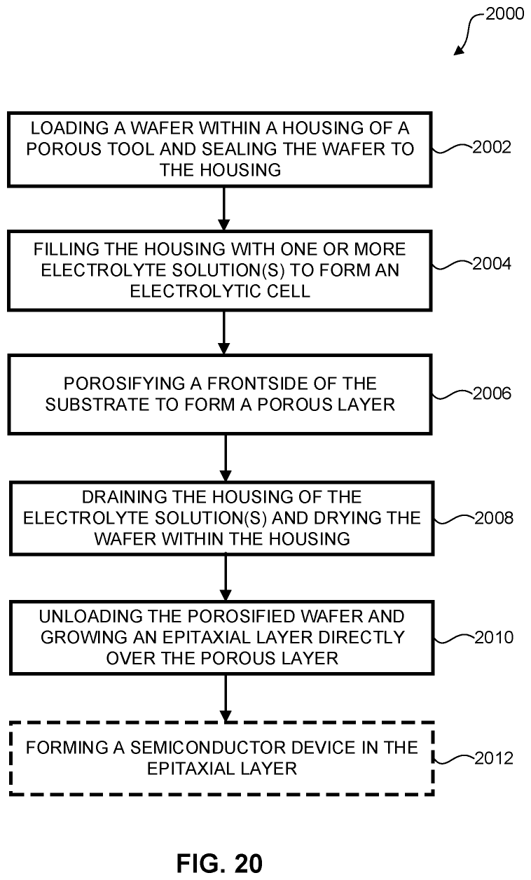

The aspects of flow diagram 1700 shown in FIG. 17, for example, and the aspects of flow diagram 2000 shown in FIG. 20 may be similar. Similar reference numbers are used to indicate features of the aspects of flow diagram 1700 shown in FIG. 17 and the similar features of the aspects of flow diagram 2000 shown in FIG. 20.

FIG. 20 illustrates flow diagram 2000 to describe the process of forming porous layered structures 300″″, 300″″′ using a dry-in and dry-out wafer porosification process (e.g., porous tool 200″ shown in FIG. 6, porous tool 200″′ shown in FIG. 7, porous tool system 800 shown in FIG. 8), according to an exemplary aspect. It is to be appreciated that not all steps in FIG. 20 are needed to perform the disclosure provided herein. Further, some of the steps can be performed simultaneously, sequentially, and/or in a different order than shown in FIG. 20. Flow diagram 2000 shall be described with reference to FIGS. 5-8, 11, 12, 15, and 16. However, flow diagram 2000 is not limited to those example aspects.

As shown in FIG. 20, flow diagram 2000 describes a dry-in and dry-out wafer porosification process to form porous layered structures 300″″, 300″″′ shown in FIGS. 11 and 12, respectively. In step 2002, as shown in the examples of FIGS. 5-8, a wafer 302 is loaded into housing 220″, 220′″ of porous tool 200″, 200″′ and sealed to housing 220″, 220″, respectively (e.g., dry-in process). In some aspects, wafer 302 is loaded into housing 220″, 220″′ of porous tool 200″, 200′″ via wafer handling system 260. For example, as shown in FIG. 8, load arm 262 can transfer a wafer 302 into housing 220′″ of porous tool 200″′ in a loading step 266. In some aspects, wafer 302 is sealed to housing 220″, 220′″ via seal 221 or via first and second seals 221a', 221b', respectively. For example, as shown in FIG. 8, wafer 302 can be between first and second seals 221a', 221b′ with first seal 221a′ sealing frontside 302a of wafer 302 and second seal 221 b′ sealing backside 302 b of wafer 302.

In step 2004, as shown in the examples of FIGS. 5-8, housing 220″, 220″′ is filled with one or more electrolyte solution(s) to form electrolytic cell 225. In some aspects, housing 220″, 220′″ is filled with an electrolyte solution (e.g., buffered HF acid) via input line 242 or first and second input lines 242a, 242b, respectively. For example, first and second input lines 242a, 242b can flow buffered HF acid into housing 220′″ to form first and second electrolytes 222a, 222b (e.g., buffered HF acid), respectively. In some aspects, housing 220″, 220′″ is filled with one or more electrolyte solutions (e.g., buffered HF acid) via input line 242 or first and second input lines 242a, 242b, respectively. For example, first input line 242a can flow a first buffered HF acid into housing 220′″ to form first electrolyte 222 a (e.g., 40% concentration buffered HF acid) and second input line 242 b can flow a second buffered HF acid into housing 220′″ to form second electrolyte 222b (e.g., 4% concentration buffered HF acid), respectively. In some aspects, first input line 242 a can flow an acid solution to form first electrolyte 222a and second input line 242b can flow a conductive solution to form second electrolyte 222b. For example, first electrolyte 222a can include buffered HF acid and second electrolyte 222b can include liquid Hg or dilute HF acid.

In step 2006, as shown in the examples of FIGS. 5-8, 15, and 16, frontside 302a of wafer 302 is porosified to form porous layer 304. In some aspects, wafer 302 can be porosified by electrolytic cell 225 of porous tool 200″, 200′″ to form porous layer 304. In some aspects, a current density per unit time (e.g., etch current density (mA/cm²)/etch time (s)) applied to electrolytic cell 225 during porosification can be controlled via controller 250. For example, as shown in FIG. 8, a dynamic feedback loop can be established between voltage source 230 and controller 250 such that the current density per unit time can be monitored and adjusted by controller 250.

In step 2008, as shown in the examples of FIGS. 5-8, housing 220″, 220″′ is drained of the electrolyte solution(s) (e.g., buffered HF acid) and wafer 302 is dried within housing 220″, 220″′. In some aspects, the electrolyte solution(s) can be drained from housing 220″, 220″′ via output line 246 or first and second output lines 246a, 246b, respectively. For example, as shown in FIG. 8, first and second output lines 246a, 246b can flow first and second electrolytes 222a, 222b (e.g., buffered HF acid) out of housing 220′″ via first and second housing controllers 240a, 240b, respectively. In some aspects, a dryer can be coupled to housing 220″, 220″′. For example, as shown in FIG. 8, dryer 280 (e.g., a spin rinse dryer, a hot plate, a furnace, an oven, an annealer, etc.) can be coupled to housing 220″′. In some aspects, dryer 280 can include a spin rinse dryer. For example, dryer 280 can rotate wafer 302 about a central axis 284 in order to dry wafer 302 after a porosification process. In some aspects, the spin rinse dryer (e.g., dryer 280 shown in FIG. 8) can spin the wafer 302 while spraying the wafer 302 with an inert gas (e.g., N, Ar, etc.) and/or another chemical (e.g., DI water) to dry the whole wafer 302 (e.g., via centrifugal forces and/or heated inert gas). In some aspects, dryer 280 can include a hot plate, a furnace, or an oven for a long duration bake. In some aspects, dryer 280 can include an annealer (e.g., flash lamp annealer) for a short duration bake (e.g., rapid thermal anneal).

In step 2010, as shown in the examples of FIGS. 5-8, 15, and 16, wafer 302 with porous layer 304 is unloaded from housing 220″, 220′″ of porous tool 200″, 200″′, respectively (e.g., dry-out process) and an epilayer 306 is grown over porous layer 304. In some aspects, wafer 302 is unloaded from housing 220″, 220′″ of porous tool 200″, 200″′ via wafer handling system 260. For example, as shown in FIG. 8, load arm 262 can transfer wafer 302 out of housing 220′″ of porous tool 200″′ in an unloading step 268. In some aspects, wafer 302 with porous layer 304 can be annealed prior to an epitaxial growth process. For example, as shown in FIG. 8, wafer 302 can be annealed in heater 272 of wafer handling system 260 prior to forming epilayer 306.

In step 2012, as shown in the examples of FIGS. 11 and 12, a semiconductor device 310 is formed in epilayer 306 to form porous layered structure 300″″, 300″″′. In some aspects, semiconductor device 310 in epilayer 306 can include a passive device (e.g., an inductor, a filter, etc.). In some aspects, semiconductor device 310 in epilayer 306 can include an RF device (e.g., an RF inductor, an RF filter, etc.). In some aspects, a plurality of semiconductor devices can be formed in epilayer 306. For example, as shown in FIG. 3B, a plurality of semiconductor devices 310a, 310b, 310c can be formed in epilayer 306 to form porous layered structure 300′.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A porous tool system comprising:
a porous tool for porosifying a wafer the porous tool comprising:
an electrolytic cell comprising a cathode, an anode, and an electrolyte the wafer configured to be between the cathode and the anode;
a housing enclosing the electrolytic cell and configured to receive the wafer for a porosification process, the housing comprising a seal, an input line, and an output line; and
a voltage source coupled to the cathode and the anode;
a wafer handling system configured to load and unload the wafer to and from the porous tool; and
a controller coupled to the porous tool and the wafer handling system, the controller configured to control the porosification process of the wafer; and
wherein the porous tool system is configured to:
load the wafer within the housing via the wafer handling system;
seal the wafer to the housing via the seal;
fill the housing with an electrolyte solution via the input line;
perform the porosification process of the wafer;
drain the housing of the electrolyte solution via the output line;
dry the wafer within the housing; and
unload the wafer via the wafer handling system after porosification.

2. The porous tool system of claim 1, wherein a diameter of the wafer is at least 200 mm.

3. The porous tool system of claim 1, wherein the porous tool system is configured to:
load the wafer within the housing via the wafer handling system;
seal the wafer to the housing via the seal;
fill the housing with deionized (DI) water via the input line;
perform a leak check of the sealed wafer;
drain the housing of the DI water via the output line;
fill the housing with an electrolyte solution via the input line;
perform the porosification process of the wafer;
drain the housing of the electrolyte solution via the output line;
flush the housing with DI water via the input line;
drain the housing of the DI water via the output line;
dry the wafer within the housing; and
unload the wafer via the wafer handling system after porosification.

4. The porous tool system of claim 1, wherein the wafer handling system is configured to automatically process a cassette of wafers.

5. The porous tool system of claim 1, further comprising a dryer coupled to the porous tool and configured to dry the wafer within the housing and/or a heater coupled to the wafer handling system and configured to heat the wafer.

6. A method for a dry-in and dry-out porosification process, the method comprising the ordered steps of:
loading a wafer within a housing of a porous tool;
sealing the wafer to the housing;
filling the housing with an electrolyte solution to form an electrolytic cell;
porosifying a portion of the wafer to form a porous layer;
draining the housing of the electrolyte solution;
drying the wafer within the housing; and
unloading the wafer.

7. The method of claim 6, wherein porosifying comprises holding the wafer vertically within the housing such that only a first side of the wafer is porosified.

8. The method of claim 6, further comprising:
filling the housing with deionized (DI) water prior to forming the electrolytic cell;
performing a leak check of the sealed housing and wafer; and
draining the housing of the DI water.

9. The method of claim 6, further comprising:
flushing the housing with DI water prior to drying the wafer; and
draining the housing of the DI water.

10. The method of claim 9, further comprising adding a floating layer of alcohol to an upper surface of the DI water prior to draining the housing of the DI water thereby forming an alcohol coating on a frontside of the wafer.

11. The method of claim 6, further comprising diluting the electrolyte solution with DI water until the electrolyte solution has a pH of about 7 (neutral) prior to draining the housing of the electrolyte solution.

12. The method of claim 6, wherein porosifying comprises controlling a current density per unit time applied to the electrolytic cell via a controller

13. The method of claim 12, wherein:
controlling comprises monitoring and adjusting the current density per unit time via a dynamic feedback loop between the controller and the porous tool based on a characteristic of the formed porous layer, and
the characteristic of the porous layer comprises a porosification rate, a porosification depth, a porosity, a resistivity, a surface roughness, or a combination thereof.

14. The method of claim 6, further comprising heating the wafer.

15. The method of claim 6, further comprising growing an epitaxial layer directly over the porous layer.

16. The method of claim 6, further comprising forming a semiconductor device in the porous layer or in the epitaxial layer.
